(19) United States
(12) Patent Application Publication
(10) Pub. No.: US 2024/0185383 A1
(43) Pub. Date: Jun. 6, 2024

(54) METHOD OF PROCESSING IMAGE BASED ON SUPER-RESOLUTION WITH DEEP LEARNING AND METHOD OF PREDICTING CHARACTERISTIC OF SEMICONDUCTOR DEVICE USING THE SAME

(71) Applicant: SAMSUNG ELECTRONICS CO., LTD., SUWON-SI (KR)

(72) Inventors: Jinseok HONG, SUWON-SI (KR); Junhee SEOK, SEOUL (KR); Jangwon SEO, SEOUL (KR); Kyuil LEE, SUWON-SI (KR)

(73) Assignee: KOREA UNIVERSITY RESEARCH AND BUSINESS FOUNDATION, SEOUL (KR)

(21) Appl. No.: 18/448,590

(22) Filed: Aug. 11, 2023

(30) Foreign Application Priority Data
Oct. 25, 2022 (KR) 10-2022-0138121

(51) Int. Cl. G06T 3/40; G06T 7/00

(52) U.S. Cl. CPC G06T 3/4046; G06T 3/4007; G06T 3/4053; G06T 7/001; G06T 2207/20016; G06T 2207/20081; G06T 2207/20084; G06T 2207/30148

(57) ABSTRACT

A method of processing an image based on super-resolution includes: sequentially performing a plurality of computing operations on a low-resolution input image using a super-resolution convolutional neural network (SRCNN) to generate a residual image, performing an interpolation operation on the low-resolution input image to generate an interpolation image and adding the residual image to the interpolation image to generate a high-resolution image. The high-resolution output image has a resolution higher than that of the low-resolution input image. The SRCNN includes a plurality of computation layers for performing the plurality of computing operations. The plurality of computation layers include a plurality of convolutional layers, and a deconvolutional layer for post-up-sampling. The deconvolutional layer is a last computation layer among the plurality of computation layers.

### CROSS-REFERENCE TO RELATED APPLICATION

This U.S. patent application claims priority under 35 USC § 119 to Korean Patent Application No. 10-2022-0138121 filed on Oct. 25, 2022 in the Korean Intellectual Property Office (KIPO), the disclosure of which is incorporated by reference in its entirety herein.

### 1. TECHNICAL FIELD

Example embodiments relate generally to semiconductor integrated circuits, and more particularly to methods of processing images based on super-resolution with deep learning, and methods of predicting characteristics of semiconductor devices using the methods of processing images.

### 2. DISCUSSION OF RELATED ART

Super-resolution (SR) is a process of recovering or reconstructing a high-resolution (HR) image/video from a corresponding low-resolution (LR) image/video. Super-resolution has been widely employed in various computer vision tasks, such as security surveillance, medical photography. With the rapid development of machine learning, such as deep learning, super-resolution algorithms based on machine learning have been studied extensively. Deep learning is based on artificial neural networks with representation learning.

For example, a typical approach regarding the construction of the high-resolution image/video is by learning a non-linear mapping from low-resolution image/video to high-resolution image/video using a convolutional neural network (CNN). The CNN is a class of artificial neural network that uses a mathematical operation referred to as a convolution in place of a general matrix multiplication in at least one of its layers.

### SUMMARY

At least one example embodiment of the present disclosure provides a method of processing an image based on super-resolution capable of efficiently generating a high-resolution image using a neural network model.

At least one example embodiment of the present disclosure provides a method of predicting a characteristic of a semiconductor device using the method of processing the image based on super-resolution.

A method of processing an image based on super-resolution according to an example embodiment includes: sequentially performing a plurality of computing operations on a low-resolution input image using a super-resolution convolutional neural network (SRCNN) to generate a residual image, performing an interpolation operation on the low-resolution input image to generate an interpolation image, and adding the residual image to the interpolation image to generate a high-resolution output image. The high-resolution output image has a resolution higher than that of the low-resolution input image. The SRCNN includes a plurality of computation layers for performing the plurality of computing operations. The plurality of computation layers include a plurality of convolutional layers, and a deconvolutional layer for post-up-sampling. The deconvolutional layer is a last computation layer among the plurality of computation layers.

A method of predicting a characteristic of a semiconductor device according to an example embodiment includes: obtaining high-resolution output characteristic data using low-resolution input characteristic data and a super-resolution convolutional neural network (SRCNN), and checking the characteristic of the semiconductor device using the high-resolution output characteristic data. The high-resolution output characteristic data and the low-resolution input characteristic data are associated with the semiconductor device. The obtaining of the high-resolution output characteristic data includes: sequentially performing a plurality of computing operations on the low-resolution input characteristic data using the SRCNN to generate residual characteristic data, performing an interpolation operation on the low-resolution input characteristic data to generate interpolation characteristic data and adding the residual characteristic data to the interpolation characteristic data to generate the high-resolution output characteristic data. The high-resolution output characteristic data has a resolution higher than that of the low-resolution input characteristic data. The SRCNN includes a plurality of computation layers for performing the plurality of computing operations. The plurality of computation layers include a plurality of convolutional layers, and a deconvolutional layer for post-up-sampling. The deconvolutional layer is a last computation layer among the plurality of computation layers.

A method of predicting light efficiency of an image sensor includes: sequentially performing a plurality of computing operations on a low-resolution input image using a super-resolution convolutional neural network (SRCNN) to generate a residual image, performing a bicubic interpolation operation on the low-resolution input image to generate an interpolation image, adding the residual image to the interpolation image to generate a high-resolution output image, and predicting the light efficiency of a plurality of pixels of the image sensor using the high-resolution output image. The high-resolution output image has a resolution higher than that of the low-resolution input image. The SRCNN includes a plurality of convolutional layers, a plurality of leaky rectified linear unit (RELU) layers, and a deconvolutional layer for post-up-sampling. The plurality of convolutional layers and the plurality of leaky RELU layers are alternately arranged. The deconvolutional layer is a last layer of the SRCNN. Each of the residual image and the interpolation image has a resolution higher than that of the low-resolution input image and equal to that of the high-resolution output image.

In a method of processing an image based on super-resolution according to an example embodiment, the high-resolution image may be generated by applying the low-resolution image to the super-resolution convolutional neural network model based on residual learning and post-up-sampling. During a learning or training process, overfitting and gradient vanishing may be resolved, and the amount of computations may be reduced. In addition, an image closer to a real image may be generated within a relatively short time. Accordingly, the image processing performance and efficiency may be increased.

In a method of predicting a characteristic of a semiconductor device according to an example embodiment, a high-resolution characteristic data may be generated by applying the low-resolution characteristic data to the super-resolution convolutional neural network. A larger amount of output characteristic values may be obtained from a smaller amount of input characteristic values, and characteristic values with increased accuracy may be obtained within a relatively short time. Accordingly, the design and manufacturing efficiency of the semiconductor devices may be increased.

### BRIEF DESCRIPTION OF THE DRAWINGS

Illustrative, non-limiting example embodiments will be more clearly understood from the following detailed description taken in conjunction with the accompanying drawings.

FIG. 1 is a flowchart illustrating a method of processing an image based on super-resolution according to an example embodiment.

FIGS. 2 and 3 are block diagrams illustrating an image processing device according to an example embodiment.

FIGS. 4A, 4B and 4C are diagrams illustrating examples of a low-resolution image and a high-resolution image, which are an input and an output of an image processing device of FIG. 2.

FIGS. 5A, 5B, 5C, 6A, 6B and 6C are diagrams for describing a super-resolution convolutional network model, which is used in a method of processing an image based on super-resolution according to an example embodiment.

FIG. 7 is a block diagram illustrating an example of a high-resolution image obtaining module included in an image processing device of FIG. 2.

FIG. 8 is a flowchart illustrating a method of processing an image based on super-resolution according to an example embodiment.

FIG. 9 is a block diagram illustrating an image processing device according to an example embodiment.

FIG. 10 is a flowchart illustrating an example of performing a training process in FIG. 8.

FIG. 11 is a flowchart illustrating an example of checking an error value of a trained super-resolution convolutional network model in FIG. 10.

FIG. 12 is a block diagram illustrating an example of a training module included in an image processing device of FIG. 9.

FIGS. 13, 14A, 14B, 14C, 15A, 15B, 15C, 15D, 15E and 16 are diagrams for describing performance of a method of processing an image based on super-resolution according to example embodiments.

FIG. 17 is a flowchart illustrating a method of predicting a characteristic of a semiconductor device according to an example embodiment.

FIG. 18 is a flowchart illustrating an example of obtaining high-resolution output characteristic data in FIG. 17.

FIG. 19 is a block diagram illustrating a characteristic predicting device according to an example embodiment.

FIG. 20 is a block diagram illustrating an image sensor, which is an example of a target to which a method of predicting a characteristic of a semiconductor device according to example an embodiment is applied.

FIG. 21 is a circuit diagram illustrating an example of a pixel included in a pixel array included in an image sensor of FIG. 20.

FIGS. 22A and 22B are diagrams illustrating examples of pixel structures of an image sensor of FIG. 20.

FIG. 23 is a flowchart illustrating a method of predicting a characteristic of a semiconductor device according to an example embodiment.

FIG. 24 is a flowchart illustrating an example of performing a training process in FIG. 23.

FIG. 25 is a block diagram illustrating a characteristic predicting device according to an example embodiment.

FIG. 26 is a flowchart illustrating a method of designing a semiconductor device according to an example embodiment.

FIG. 27 is a flowchart illustrating a method of manufacturing a semiconductor device according to an example embodiment.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

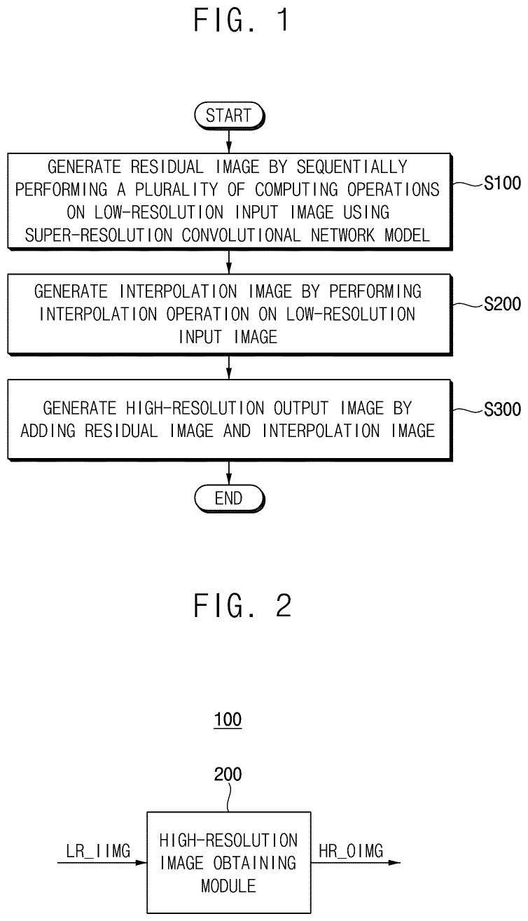

FIG. 1 is a flowchart illustrating a method of processing an image based on super-resolution according to an example embodiment.

Referring to FIG. 1, a method of processing an image based on super-resolution according to an example embodiment is performed by an image processing device. A detailed configuration of the image processing device will be described with reference to FIGS. 2, 3, 7 and/or the like.

In the method of processing the image based on super-resolution according to an example embodiment, a residual image (or residual data) is generated by sequentially performing a plurality of computing operations (e.g., computation or calculation) on a low-resolution input image (or low-resolution input data) using a super-resolution convolutional network model (or convolutional neural network model) (operation S100). The super-resolution convolutional network model may be based on residual learning and post-up-sampling.

In an embodiment, the super-resolution convolutional network model is implemented based on a neural network, for example, based on a convolutional neural network (CNN) or a super-resolution CNN (SRCNN). There are various methods of processing and/or classifying data based on machine learning. Among them, a method of processing and/or classifying data using a neural network or an artificial neural network (ANN) is one example. The neural network is obtained by engineering a cell structure model of a human brain where a process of efficiently recognizing a pattern is performed. The neural network refers to a calculation model that is based on software or hardware and is designed to imitate biological calculation abilities by applying many artificial neurons interconnected through connection lines. The human brain consists of neurons that are basic units of a nerve, and encrypts or decrypts information according to different types of dense connections between these neurons. Artificial neurons in the neural network are obtained through simplification of biological neuron functionality. The neural network performs a cognition or learning process by interconnecting the artificial neurons having connection intensities.

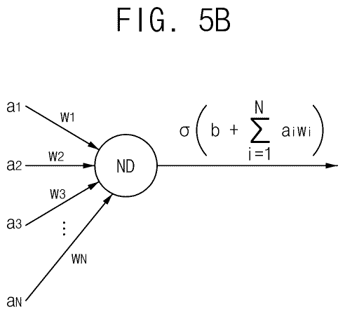

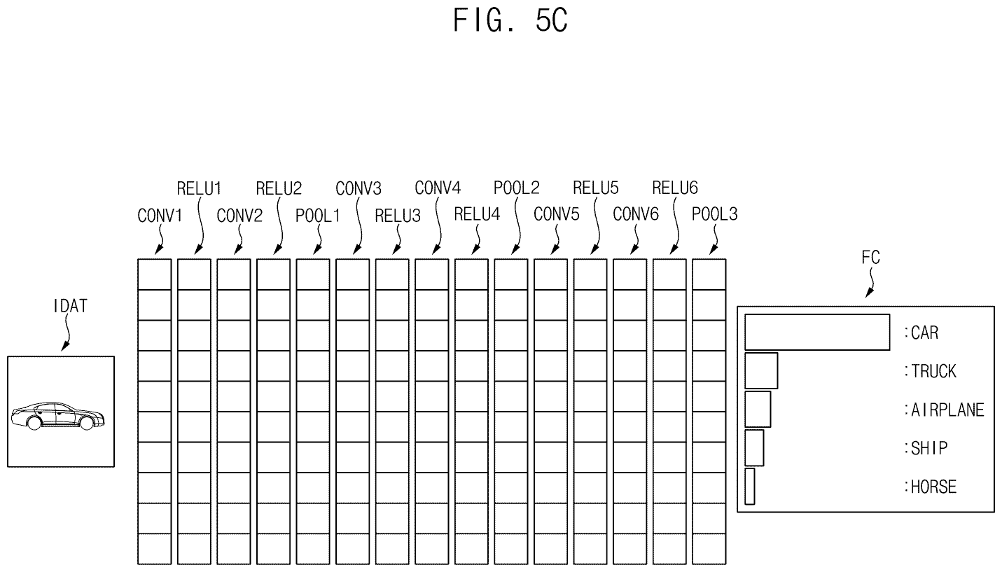

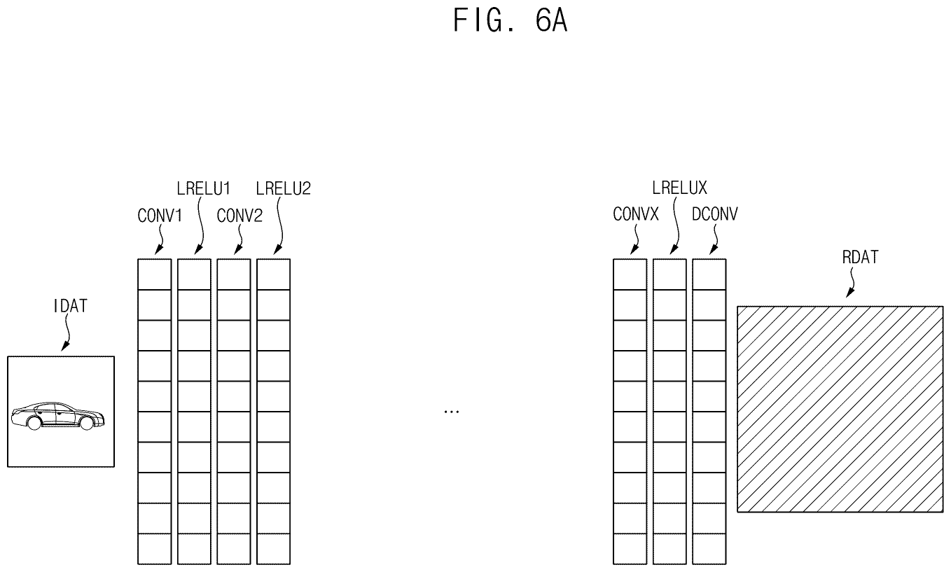

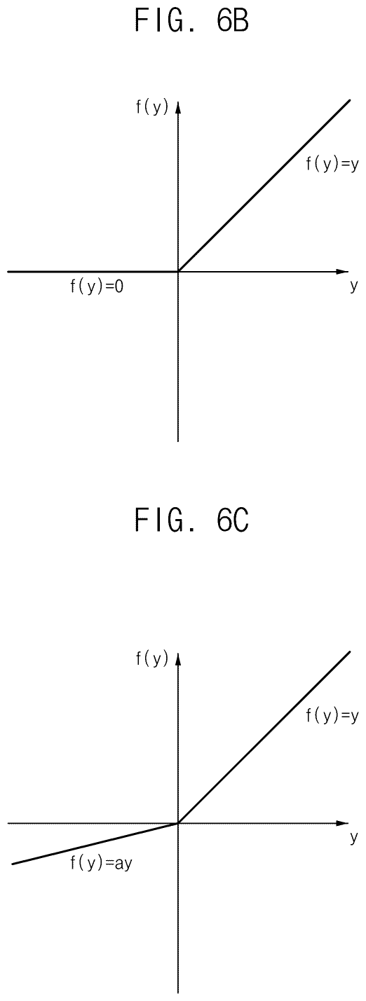

For example, the super-resolution convolutional network model may include a plurality of computation layers (or calculation layers or operation layers) for performing the plurality of computing operations. In an embodiment, the plurality of computation layers include a plurality of convolutional layers, and a deconvolutional layer for the post-up-sampling. In an embodiment, the deconvolutional layer is a last computation layer among the plurality of computation layers. The super-resolution convolutional network model will be described with reference to FIGS. 5A, 5B, 5C, 6A, 6B and 6C.

An interpolation image (or interpolation data) is generated by performing an interpolation operation on the low-resolution input image (operation S200). A high-resolution output image (or high-resolution output data) is obtained by adding the residual image and the interpolation image (operation S300). For example, the residual image is added to the interpolation image to generate the high-resolution output image. The high-resolution output image has a resolution higher than a resolution of the low-resolution input image.

In an example embodiment, each of the residual image and the interpolation image have a resolution higher than a resolution of the low-resolution input image. In an example embodiment, each of the residual image and the interpolation image has a resolution substantially equal to or the same as a resolution of the high-resolution output image.

Super-resolution (SR) is a process of recovering or reconstructing a high-resolution (HR) image/video from a corresponding low-resolution (LR) image/video, and may be employed in computer vision tasks. Super-resolution of an image may be classified into single image super-resolution (SISR) and multi image super-resolution (MISR) according to the number of images used.

A method of processing the image based on super-resolution according to an example embodiment is associated with or related to the single image super-resolution. In the method of processing the image based on super-resolution according to an example embodiment, the high-resolution image may be generated by applying the low-resolution image to the super-resolution convolutional network model. For example, features of the low-resolution image may be applied to an input layer of a super-resolution convolutional neural network. The super-resolution convolutional network model may be implemented using residual learning and post-up-sampling, and thus overfitting and gradient vanishing may be resolved and the amount of computations may be reduced during learning or training process. In addition, when the high-resolution image is generated using the super-resolution convolutional network model, an image closer to a real image may be generated within a relatively short time. For example, a user is more likely to perceive the high-resolution image generated by the model as being originally captured by an image sensor such as a camera. Accordingly, the image processing performance and efficiency may be increased.

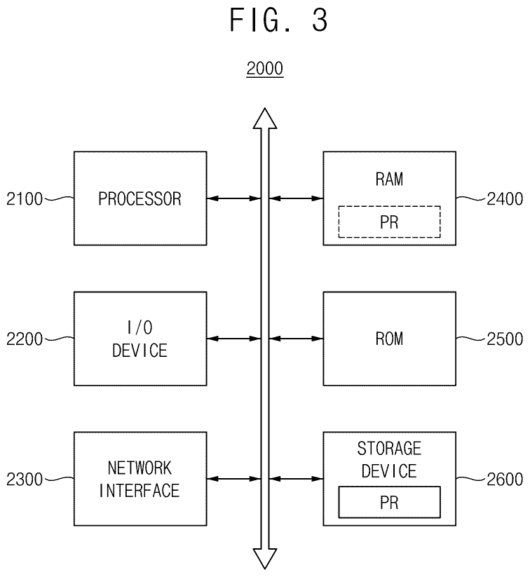

FIGS. 2 and 3 are block diagrams illustrating an image processing device according to an example embodiment.

Referring to FIG. 2, an image processing device 100 includes a high-resolution image obtaining module 200.

Herein, the term “module” may indicate, but is not limited to, a software and/or hardware component, such as a field programmable gate array (FPGA) or an application specific integrated circuit (ASIC), which performs certain tasks. A module may be configured to reside in a tangible addressable storage medium and may be configured to execute on one or more processors. For example, a “module” may include components such as software components, object-oriented software components, class components and task components, and processes, functions, routines, segments of program code, drivers, firmware, microcode, circuitry, data, databases, data structures, tables, arrays, and variables. A “module” may be divided into a plurality of “modules” that perform detailed functions.

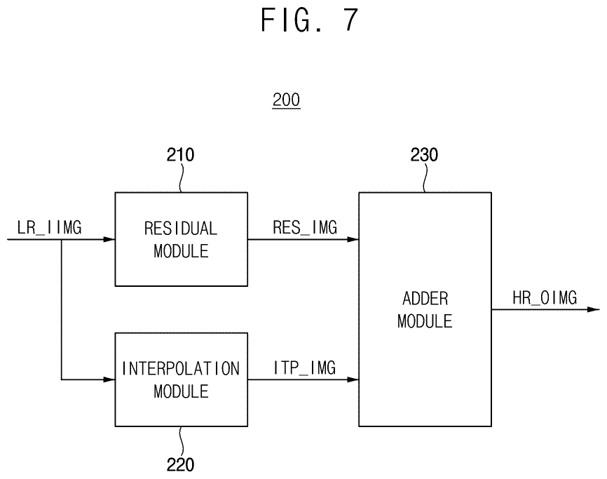

The high-resolution image obtaining module 200 obtains and/or generates a high-resolution output image HR_OIMG based on a low-resolution input image LR_IIMG. For example, the high-resolution image obtaining module 200 may operate by executing a super-resolution convolutional network model based on residual learning and post-up-sampling. For example, the high-resolution image obtaining module 200 may generate a residual image by sequentially performing a plurality of computing operations on the low-resolution input image LR_IIMG using the super-resolution convolutional network model, may generate an interpolation image by performing an interpolation operation on the low-resolution input image LR_IIMG, and may generate the high-resolution output image HR_OIMG by adding the residual image and the interpolation image. For example, the residual image may be added to the interpolation image to generate the high-resolution output image HR_OIMG. In other words, the high-resolution image obtaining module 200 may perform operations S100, S200 and S300 in FIG. 1. A detailed configuration of the high-resolution image obtaining module 200 will be described with reference to FIG. 7.

At least some functionality of the high-resolution image obtaining module 200 may be implemented in software, which when stored in a memory is executable by a processor, but example embodiments are not limited thereto. When the high-resolution image obtaining module 200 is implemented in software, the high-resolution image obtaining module 200 may be stored in the form of executable code in a storage device.

Referring to FIG. 3, an image processing device 2000 includes a processor 2100, an input/output (I/O) device 2200, a network interface 2300 (e.g., a network card or netword interface circuit), a random access memory (RAM) 2400, a read only memory (ROM) 2500 and a storage device 2600. FIG. 3 illustrates an example where the high-resolution image obtaining module 200 in FIG. 2 is implemented in software.

The image processing device 2000 may be included in a computing system. For example, the computing system may be a fixed computing system such as a desktop computer, a workstation or a server, or may be a portable computing system such as a laptop computer.

The processor 2100 may be used by the high-resolution image obtaining module 200 in FIG. 2 to perform computations or calculations. For example, the processor 2100 may include a micro-processor, an application processor (AP), a central processing unit (CPU), a graphic processing unit (GPU), a neural processing unit (NPU), or the like. For example, the processor 2100 may include a core or a processor core for executing an arbitrary instruction set (for example, intel architecture-32 (IA-32), 64-bit extension IA-32, x86-64, PowerPC, Sparc, MIPS, ARM, IA-64, etc.). For example, the processor 2100 may access a memory (e.g., the RAM 2400 or the ROM 2500) through a bus, and may execute instructions stored in the RAM 2400 or the ROM 2500. As illustrated in FIG. 3, the RAM 2400 may store a program PR corresponding to the high-resolution image obtaining module 200 in FIG. 2 or at least some elements (e.g., instructions) of the program PR, and the program PR may allow the processor 2100 to perform operations (e.g., operations S100, S200 and S300 in FIG. 1) for obtaining the high-resolution image.

In other words, the program PR may include a plurality of instructions and/or procedures executable by the processor 2100, and the plurality of instructions and/or procedures included in the program PR may allow the processor 2100 to perform the method of processing the image based on super-resolution according to example embodiments. Each of the procedures may denote a series of instructions for performing a certain task. A procedure may be referred to as a function, a routine, a subroutine, or a subprogram. Each of the procedures may process data provided from the outside and/or data generated by another procedure. For example, the data provided from the outside may be data received from an external device located external to the image processing device 2000.

In some example embodiments, the RAM 2400 may include a volatile memory such as a static random access memory (SRAM), a dynamic random access memory (DRAM), or the like.

The storage device 2600 may store the program PR. The program PR, or at least some elements of the program PR, may be loaded from the storage device 2600 to the RAM 2400 before being executed by the processor 2100. The storage device 2600 may store a file written in a program language, and the program PR, which may be generated by a compiler or the like, or at least some elements of the program PR, may be loaded to the RAM 2400. For example, the program PR may be copied from the storage device 2600 to the RAM 2400.

The storage device 2600 may store data, which is to be processed by the processor 2100, or data obtained through processing by the processor 2100. The processor 2100 may process the data stored in the storage device 2600 to generate new data, based on the program PR and may store the generated data in the storage device 2600.

In some example embodiments, the storage device (or storage medium) 2600 may include any non-transitory computer-readable storage medium used to provide commands and/or data to a computer. For example, the non-transitory computer-readable storage medium may include a volatile memory such as an SRAM, a DRAM, or the like, and a nonvolatile memory such as a flash memory, a magnetic random access memory (MRAM), a phase-change random access memory (PRAM), a resistive random access memory (RRAM), or the like. The non-transitory computer-readable storage medium may be inserted into the computer, may be integrated in the computer, or may be coupled to the computer through a communication medium such as a network and/or a wireless link.

In an example embodiment, the storage device 2600 is a solid state drive (SSD). In other example embodiments, the storage device 2600 may be a universal flash storage (UFS), a multi-media card (MMC) or an embedded multi-media card (eMMC). Alternatively, the storage device 2600 may be one of a secure digital (SD) card, a micro SD card, a memory stick, a chip card, a universal serial bus (USB) card, a smart card, a compact flash (CF) card, or the like.

The I/O device 2200 may include an input device, such as a keyboard, a pointing device, or the like, and may include an output device such as a display device, a printer, or the like. For example, a user may trigger, through the I/O devices 2200, execution of the program PR by the processor 2100 or may provide various inputs, and may check input data, output data, a result of training, and/or an error message, etc.

The network interface 2300 may provide access to a network located outside the image processing device 2000. For example, the network may include a plurality of computing systems and communication links, and the communication links may include wired links, optical links, wireless links, or arbitrary other type links. Various inputs may be provided to the image processing device 2000 through the network interface 2300, and various outputs may be provided to another computing system through the network interface 2300.

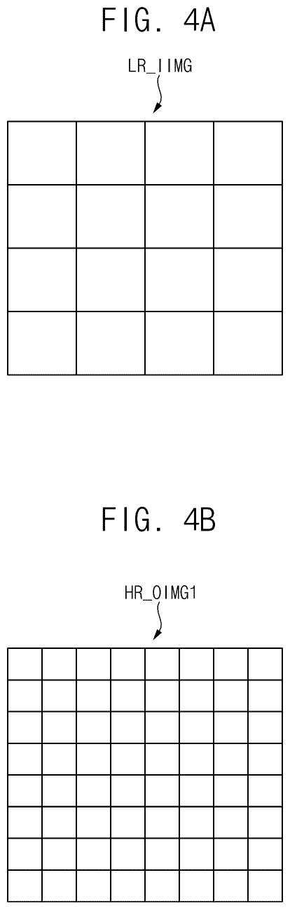

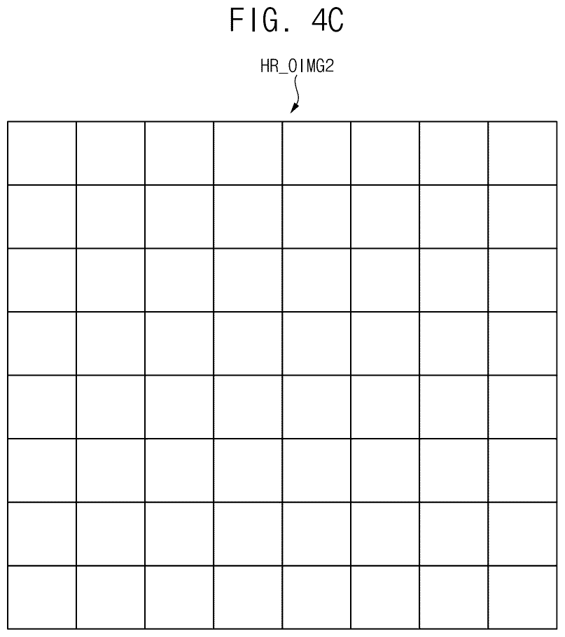

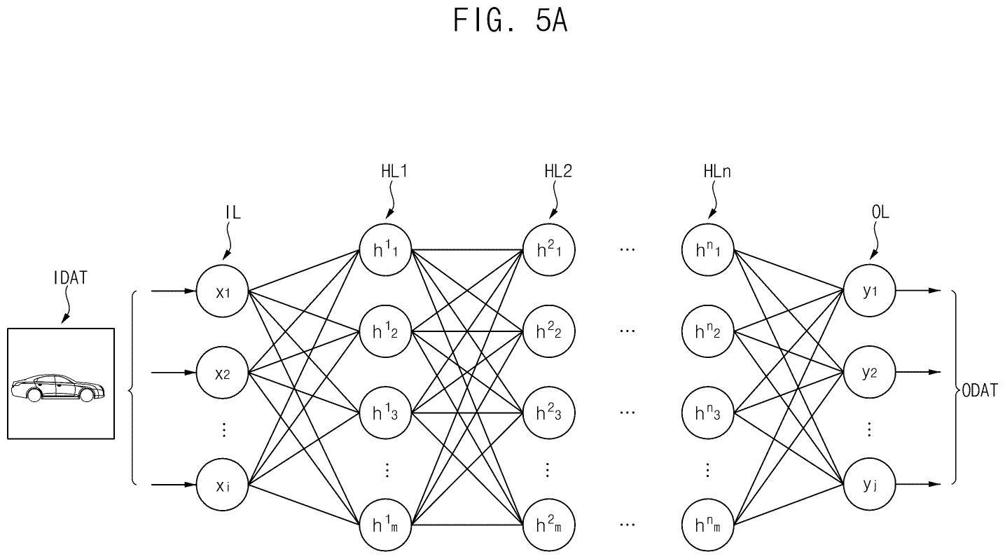

FIGS. 4A, 4B and 4C are diagrams illustrating examples of a low-resolution image and a high-resolution image, which are an input and an output of an image processing device of FIG. 2.

Referring to FIG. 4A, an example of the low resolution input image LR_IIMG that is provided and/or input to the image processing device 100 of FIG. 2 is illustrated. For example, FIG. 4A illustrates an example where the low-resolution input image LR IIMG is represented by 4*4=16 pixels. In FIG. 4A and subsequent figures, one small square may correspond to one pixel.

Referring to FIGS. 4B and 4C, examples of the high-resolution output image HR OIMG that is generated and/or output from the image processing device 100 of FIG. 2 are illustrated. For example, FIG. 4B illustrates an example where a first high-resolution output image HR_OIMG1 is represented by 8*8=64 pixels and FIG. 4C illustrates an example where a second high-resolution output image HR OIMG2 is also represented by 8*8=64 pixels.

Resolution of image or image resolution may refer to the detail an image holds, and this term may apply to digital images, film images, and other types of images. “Higher resolution” may mean more image detail. Resolution may be measured in various ways, and resolution units may be tied to physical sizes (e.g., lines per milimeter, lines per inch), to the overall size of a picture (lines per picture height, also known simply as lines, TV lines, or TVL), or to angular subtense. For example, the term resolution may be considered equivalent to pixel count in digital imaging, and may be represented as number of effective pixels, pixels per inch (PPI), and/or the like.

In an example embodiment, as illustrated in FIGS. 4A and 4B, the overall size of the low-resolution input image LR_IIMG and the high-resolution output image HR_OIMG1 are substantially equal to each other, and the size of one pixel in the high-resolution output image HR_OIMG1 is smaller than the size of one pixel in the low-resolution input image LR_IIMG.

In an example embodiment, as illustrated in FIGS. 4A and 4C, the size of one pixel in the low-resolution input image LR_IIMG and the size of one pixel in the high-resolution output image HR_OIMG2 are equal to each other or substantially equal to each other, and the overall size of the high-resolution output image HR_OIMG2 is greater than the overall size of the low-resolution input image LR_IIMG.

FIGS. 5A, 5B, 5C, 6A, 6B and 6C are diagrams for describing a super-resolution convolutional network model, which is used in a method of processing an image based on super-resolution according to an example embodiment.

FIGS. 5A, 5B and 5C illustrate configurations of neural networks, prior to describing the super-resolution convolutional network model according to example embodiments. FIG. 6A illustrates a configuration of the super-resolution convolutional network model according to an example embodiment. FIG. 6B illustrates an activation function with respect to a general rectified linear unit (RELU) operation, and FIG. 6C illustrates an activation function with respect to a leaky RELU operation included in the super-resolution convolutional network model according to an example embodiment. In an embodiment, the leaky RELU operation is a type of activation function based on ReLU, but it has a small slope for negative values instead of a flat slope.

Referring to FIG. 5A, a general neural network (or artificial neural network) may include an input layer IL, a plurality of hidden layers HL1, HL2, . . . , HLn and an output layer OL.

The input layer IL may include i input nodes x₁, x₂, . . . , xᵢ, where i is a natural number. Input data or vector input data (e.g., input image) IDAT whose length is i may be input to the input nodes x₁ to xᵢ such that each element of the input data IDAT is input to a respective one of the input nodes x₁ to xᵢ. The input data IDAT may include information associated with the various features of the different classes to be categorized.

The plurality of hidden layers HL1 to HLn may include n hidden layers, where n is a natural number, and may include a plurality of hidden nodes h¹₁, h¹₂, h¹₃, . . . , h¹ₘ, h²₁, h²₂, h²₃, . . . , h²ₘ, hⁿ₁, hⁿ₂, hⁿ₃, hⁿₘ. For example, the hidden layer HL1 may include m hidden nodes h¹₁ to h¹ₘ, the hidden layer HL2 may include m hidden nodes h²₁ to h²ₘ, and the hidden layer HLn may include m hidden nodes hⁿ₁ to hⁿₘ, where m is a natural number.

The output layer OL may include j output nodes y₁, y₂, . . . , yⱼ, where j is a natural number. Each of the output nodes y₁ to yⱼ may correspond to a respective one of classes to be categorized. The output layer OL may generate output values (e.g., class scores, numerical output such as a regression variable, or probabilities) and/or output data ODAT associated with the input data IDAT for each of the classes. For example, the probabilities may indicate how likely the input data IDAT is to be considered as corresponding to one of the classes. In some example embodiments, the output layer OL may be a fully-connected layer and may indicate, for example, a probability that the input data IDAT corresponds to a car or a certain type or make of car.

A structure of the neural network illustrated in FIG. 5A may be represented by information on branches (or connections) between nodes illustrated as lines, and a weighted value (or weight) assigned to each branch. In an embodiment of the neural network model, nodes within one layer are not connected to one another, but nodes of different layers may be fully or partially connected to one another. In an embodiment of the neural network model based on an unrestricted Boltzmann machine, at least some nodes within one layer are also connected to other nodes within one layer in addition to (or alternatively with) one or more nodes of other layers.

Each node (e.g., the node h¹₁ ) may receive an output of a previous node (e.g., the node x₁), may perform a computing operation, computation or calculation on the received output, and may output a result of the computing operation, computation or calculation as an output to a next node (e.g., the node h²₁). Each node may calculate a value to be output by applying the input to a specific function, e.g., a nonlinear function. This function may be referred to as the activation function for the node.

In an example embodiment, the structure of the neural network is set in advance, and the weighted values for the connections between the nodes are set appropriately by using sample data having a sample answer (also referred to as a “label”), which indicates a class the data corresponding to a sample input value. For example, the label may indicate which class the sample data belongs to among a plurality of available classes. The data with the sample answer may be referred to as “training data”, and a process of determining the weighted values may be referred to as “training”. The neural network “learns” to associate the data with corresponding labels during the training process. For example, the neural network may learn to classify new data into the classes using the training data. A neural network structure and weighted values of the neural network structure that have been trained using an algorithm may be referred to as a “model”, and a process of predicting, by the model with the determined weighted values, which class new input data belongs to, and then outputting the predicted value, may be referred to as a “testing” process or operating the neural network in inference mode.

Referring to FIG. 5B, an example of an operation (e.g., computation or calculation) performed by one node ND included in the neural network of FIG. 5A is illustrated in detail.

Based on N inputs a₁, a₂, a₃, . . . , a_{N} provided to the node ND, where N is a natural number greater than or equal to two, the node ND may multiply the N inputs a₁ to a_{N} and corresponding N weights w₁, w₂, w₃, . . . , w_{N}, respectively, may sum N values obtained by the multiplication to obtain a summed value, may add an offset “b” to the summed value, and may generate one output value (e.g., “z”) by applying a value to which the offset “b” is added to a specific function “σ”.

In an example embodiment and as illustrated in FIG. 5B, one layer included in the neural network illustrated in FIG. 5A includes M nodes ND, where M is a natural number greater than or equal to two, and output values of the one layer may be obtained by Equation 1.

W*A=Z [Equation 1]

In Equation 1, “W” denotes a weight set including weights for all connections included in the one layer, and may be implemented in an M*N matrix form. “A” denotes an input set including the N inputs a₁ to a_{N} received by the one layer, and may be implemented in an N*1 matrix form. “Z” denotes an output set including M outputs z₁, z₂, z₃, . . . , z_{M} output from the one layer, and may be implemented in an M*1 matrix form.

The general neural network illustrated in FIG. 5A may not be suitable for handling input image data (or input sound data) because each node (e.g., the node h¹₁) is connected to all nodes of a previous layer (e.g., the nodes x₁ to xᵢ included in the layer IL) and then the number of weighted values drastically increases as the size of the input image data increases. Thus, a convolutional neural network (CNN), which is implemented by combining a filtering technique with the general neural network of FIG. 5A may be used such that a two-dimensional image, as an example of the input image data, is efficiently trained by the convolutional neural network.

Referring to FIG. 5C, a convolutional neural network may include a plurality of layers CONV1, RELU1, CONV2, RELU2, POOL1, CONV3, RELU3, CONV4, RELU4, POOL2, CONV5, RELU5, CONV6, RELU6, POOL3 and FC. Here, “CONN” denotes a convolutional layer, “RELU” denotes a rectified linear unit layer, “POOL” denotes a pooling layer, and “FC” denotes a fully-connected layer.

Unlike the general neural network, each layer of the convolutional neural network may have three dimensions of a width, a height and a depth, and thus data that is input to each layer may be volume data having three dimensions of a width, a height and a depth. For example, if an input image in FIG. 5C has a size including a width of 32 units (e.g., 32 pixels) and a heigh of 32 units and three color channels R, G and B, input data IDAT corresponding to the input image may have a size of 32*32*3. The input data IDAT in FIG. 5C may be referred to as input volume data or input activation volume.

Each of the convolutional layers CONV1 to CONV6 may perform a convolutional operation on input volume data. In an image processing operation, the convolutional operation represents an operation in which image data is processed based on a mask with weighted values and an output value is obtained by multiplying input values by the weighted values and adding up the total multiplication results. The mask may be referred to as a filter, a window, or a kernel.

Parameters of each convolutional layer may include a set of learnable filters. Every filter may be small spatially (along a width and a height), but may extend through the full depth of an input volume. For example, during the forward pass, each filter may be slid (e.g., convolved) across the width and height of the input volume, and dot products may be computed between the entries of the filter and the input at any position. As the filter is slid over the width and height of the input volume, a two-dimensional activation map corresponding to responses of that filter at every spatial position may be generated. As a result, an output volume may be generated by stacking these activation maps along the depth dimension. For example, if input volume data having a size of 32*32*3 passes through the convolutional layer CONV1 having four filters with zero-padding, output volume data of the convolutional layer CONV1 may have a size of 32*32*12 (e.g., a depth of volume data increases).

Each of the RELU layers RELU1 to RELU6 may perform a rectified linear unit (RELU) operation that corresponds to an activation function defined by, e.g., a function f(x)=max(0, x) (e.g., an output is zero for all negative input x). For example, if input volume data having a size of 32*32*12 passes through the RELU layer RELU1 to perform the rectified linear unit operation, output volume data of the RELU layer RELU1 may have a size of 32*32*12 (e.g., a size of volume data is maintained).

Each of the pooling layers POOL1 to POOL3 may perform a down-sampling operation on input volume data along spatial dimensions of width and height. For example, four input values arranged in a 2*2 matrix formation may be converted into one output value based on a 2*2 filter. For example, a maximum value of four input values arranged in a 2*2 matrix formation may be selected based on 2*2 maximum pooling, or an average value of four input values arranged in a 2*2 matrix formation may be obtained based on 2*2 average pooling. For example, if input volume data having a size of 32*32*12 passes through the pooling layer POOL1 having a 2*2 filter, output volume data of the pooling layer POOL1 may have a size of 16*16*12 (e.g., a width and a height of volume data decreases, and a depth of volume data is maintained).

Convolutional layers may be repeatedly arranged in the convolutional neural network, and the pooling layer may be periodically inserted in the convolutional neural network, thereby reducing a spatial size of an image and for extracting a characteristic of the image.

The output layer or fully-connected layer FC may output results (e.g., class scores) of the input volume data IDAT for each of the classes. For example, the input volume data IDAT corresponding to the two-dimensional image may be converted into a one-dimensional matrix or vector, which may be referred to as an embedding, as the convolutional operation and the down-sampling operation are repeated. For example, the fully-connected layer FC may represent probabilities that the input volume data DAT corresponds to a car, a truck, an airplane, a ship and a horse.

The types and number of layers included in the convolutional neural network are not limited to the example described with reference to FIG. 5C and may be variously determined according to example embodiments. In addition, the convolutional neural network may further include other layers such as a softmax layer for converting score values corresponding to predicted results into probability values, a bias adding layer for adding at least one bias, or the like. The bias may also be incorporated into the activation function.

Referring to FIG. 6A, a super-resolution convolutional network model (or convolutional neural network model), which is used in the method of processing the image based on super-resolution according to an example embodiment, may include a plurality of layers or computation layers CONV1, LRELU1, CONV2, LRELU2, CONVX, LRELUX and DCONV for performing a plurality of computing operations, where X is a natural number greater than or equal to two.

The plurality of computation layers CONV1, LRELU1, CONV2, LRELU2, CONVX, LRELUX and DCONV may include a plurality of convolutional layers CONV1 to CONVX, and a deconvolutional layer DCONV. The plurality of computation layers CONV1, LRELU1, CONV2, LRELU2, CONVX, LRELUX and DCONV may further include a plurality of leaky RELU layers LRELU1 to LRELUX.

The plurality of convolutional layers CONV1 to CONVX may be substantially the same as the convolutional layers CONV1 to CONV6 in FIG. 5C, and may perform the convolutional operation on data input thereto.

An arrangement of the plurality of leaky RELU layers LRELU1 to LRELUX may be similar to that of the RELU layers RELU1 to RELU6 in FIG. 5C, and the plurality of convolutional layers CONV1 to CONVX and the plurality of leaky RELU layers LRELU1 to LRELUX may be alternately arranged. However, unlike the RELU layers RELU1 to RELU6 in FIG. 5C, the plurality of leaky RELU layers LRELU1 to LRELUX perform a leaky rectified linear unit operation on data input thereto.

The deconvolutional layer DCONV may perform a deconvolutional operation on data input thereto. The deconvolutional operation is an operation inverse to the convolutional operation. For example, it may be possible to recover the original signal after a filter (e.g., the convolutional operation) by using the deconvolutional operation with a certain degree of accuracy.

The super-resolution convolutional network model may be implemented by stacking (or connecting) the plurality of computation layers that perform the plurality of computing operations. The super-resolution convolutional network model according to an example embodiment may be a fast residual learning super-resolution convolutional network model (FRSR).

The super-resolution convolutional network model, which is used in the method of processing the image based on super-resolution according to an example embodiments, may be implemented based on residual learning and post-up-sampling.

Overfitting, gradient vanishing, and an increase in the amount of computations may occur as the depth of a model increases when training a neural network based on the mode. However, overfitting, gradient vanishing, and an increase in the amount of computations may be resolved or reduced as the depth of the model increases by using a result of a previous layer again according to residual learning. For example, the residual learning may be performed based on Equation 2 and Equation 3.

F(X)=H(H)−X_{identity} [Equation 2]

F(X)=H(X)−Xᵢₙₜₑᵣₚₒₗₐₜᵢₒₙ [Equation 3]

In Equation 2 and Equation 3, “X” denotes an input of each computation layer, “H(X)” denotes an output of each computation layer, and “F(X)” denotes a residual function associated with “X”. “X_{identity}” denotes the same image as “X”, and “ Xᵢₙₜₑᵣₚₒₗₐₜᵢₒₙ” denotes an image obtained by interpolating “X”. Although the output “H(X)” itself is trained or learned in the general neural network, the residual function “F(X)” may be trained or learned when the residual learning is applied. Since the residual learning is applied, residual data RDAT corresponding to the input data DAT may be generated and/or output.

In addition, the post-up-sampling may be applied to reduce the amount of computations. An up-sampling operation may be used to convert the low-resolution image into an image of the same size as the high-resolution image. When the up-sampling operation is performed before passing through the convolutional layer, it may be referred to as pre-up-sampling. When the up-sampling operation is performed after passing through the convolutional layer, it may be referred to as post-up-sampling.

With respect to the post-up-sampling, the deconvolutional layer DCONV may be the computation layer for performing the post-up-sampling, and may be arranged to correspond to the last computation layer among the plurality of computation layers CONV1, LRELU1, CONV2, LRELU2, . . . , CONVX, LRELUX and DCONV. For example, even though input volume data and output volume data of the plurality of convolutional layers CONV1 to CONVX and the plurality of leaky RELU layers LRELU1 to LRELUX have the same size, input volume data and output volume data of the deconvolutional layer DCONV may have different sizes. For example, the size of the output volume data of the deconvolutional layer DCONV may become larger than the size of the input volume data of the deconvolutional layer DCONV (e.g., a width and a height of volume data increases).

Referring to FIG. 6B, an activation function with respect to a general RELU operation performed by the RELU layers RELU1 to RELU6 in FIG. 5C is illustrated. When an input “y” is greater than or equal to zero, an output “f(y)” equal to the input “y” may be provided (e.g., f(y)=y). When the input “y” is smaller than zero, zero may be output.

Referring to FIG. 6C, an activation function with respect to a leaky RELU operation performed by the leaky RELU layers LRELU1 to LRELUX in FIG. 6A is illustrated. As with the general RELU operation, when the input “y” is greater than or equal to zero, the output “f(y)” equal to the input “y” may be provided (e.g., f(y)=y). Unlike the general RELU operation, even when the input “y” is smaller than zero, a value “a*y” proportional to the input “y” may be output, rather than zero (e.g., f(y)=a*y, where “a” is a real number greater than zero and less than one).

The general RELU operation corresponding to the activation function of FIG. 6B may turn all inputs smaller than zero into zero, a dead RELU or a dying RELU may occur. To prevent all inputs smaller than zero from being turned into zero, a leaky RELU operation that partially reflects negative numbers smaller than zero may be applied.

However, example embodiments are not limited thereto, and a parameter RELU operation, an exponential linear unit (ELU) operation, and/or the like may be applied. Alternatively or additionally, sigmoid, tanh, and/or the like may be used as an activation function.

FIG. 7 is a block diagram illustrating an example of a high-resolution image obtaining module included in an image processing device of FIG. 2.

Referring to FIG. 7, the high-resolution image obtaining module 200 may include a residual module 210, an interpolation module 220 and an adder module 230.

The residual module 210 may generate a residual image RES_IMG by sequentially performing the plurality of computing operations on the low-resolution input image LR_IIMG using the super-resolution convolutional network model. In other words, the residual module 210 may perform operation S100 in FIG. 1. For example, the residual module 210 may be implemented to execute the super-resolution convolutional network model of FIG. 6A.

The interpolation module 220 may generate an interpolation image ITP_IMG by performing the interpolation operation on the low resolution input image LR_IIMG. In other words, the interpolation module 220 may perform operation 5200 in FIG. 1.

In an example embodiment, each of the residual image RES_IMG and the interpolation image ITP_IMG have a resolution higher than a resolution of the low-resolution input image LR_IIMG, and have a resolution equal to or substantially equal to the resolution of the high-resolution output image HR_OIMG.

In an example embodiment, the interpolation module 220 generates the interpolation image ITP_IMG by performing a bicubic interpolation operation on the low-resolution input image LR_IIMG. In an embodiment, an operation of setting the resolution (or size) of the low-resolution input image LR_IIMG equal to that of the high-resolution output image HR_OIMG is performed to apply the residual learning. For example, the interpolation image ITP_IMG may be generated by performing the bicubic interpolation operation based on Equation 4. The bicubic interpolation is an extension of cubic interpolation for interpolating data points on a two-dimensional regular grid. In image processing, the bicubic interpolation may be chosen over bilinear or nearest-neighbor interpolation. In contrast to the bilinear interpolation, which only takes four pixels (2*2) into account, the bicubic interpolation considers 16 pixels (4*4).

$$f ( x , y ) = {\sum }_{i = 0}^{3} {\sum }_{j = 0}^{3} {a}_{ij} {x}^{i} {y}^{j} \qquad [ Equation 4 ]$$

The adder module 230 may generate the high-resolution output image HR_OIMG by adding the residual image RES_IMG and the interpolation image ITP_IMG. In other words, the adder module 230 may perform operation S300 in FIG. 1. For example, the adder module 230 may add the residual image RES_IMG to the interpolation image ITP_IMG to generate the high-resolution output image HR_OIMG.

In some example embodiments, at least a part of the modules 210, 220 and 230 may be implemented as hardware. For example, at least a part of the modules 210, 220 and 230 may be included in a computer-based electronic system. In other example embodiments, at least a part of the modules 210, 220 and 230 may be implemented as instruction code or program routines (e.g., a software program) that are executable by a processor when stored in a memory. For example, the instruction code or the program routines may be executed by a computer-based electronic system, and may be stored in any storage device located inside or outside the computer-based electronic system.

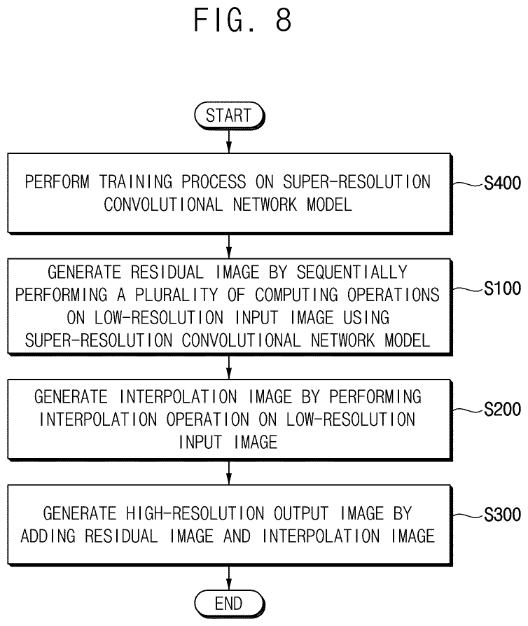

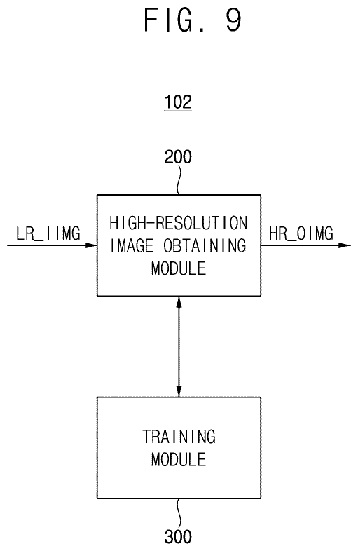

FIG. 8 is a flowchart illustrating a method of processing an image based on super-resolution according to an example embodiment. The descriptions repeated with FIG. 1 will be omitted for brevity.

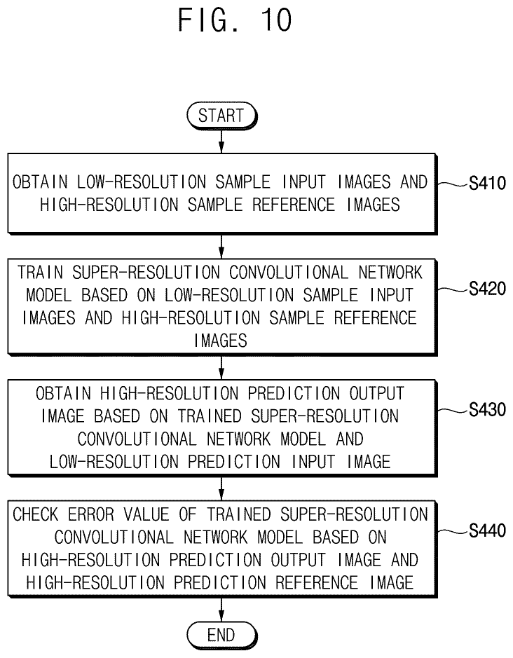

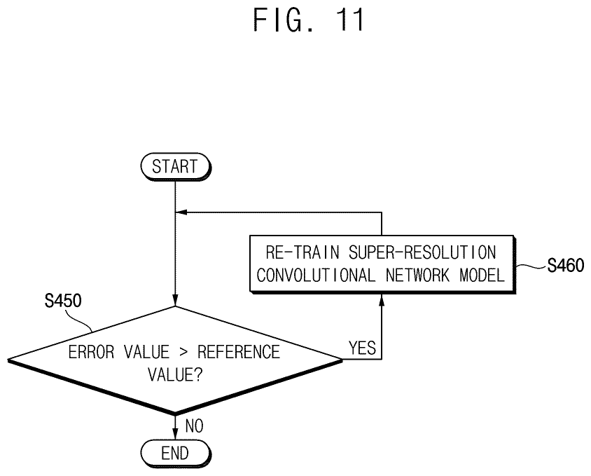

Referring to FIG. 8, in a method of processing an image based on super-resolution according to an example embodiment, before operations S100, S200 and S300, a training process is performed on the super-resolution convolutional network model (operation S400). For example, a forward propagation process and a backpropagation process may be performed on the super-resolution convolutional network model. The forward propagation process may be a portion of procedures while the training process is performed, and the backpropagation process may be another portion of procedures performed while the training process is performed. The forward propagation process may represent a process of calculating output (or output data) by passing input (or input data) through the super-resolution convolutional network model in a forward direction. The backpropagation process may represent a process of calculating loss by comparing the output with a label, which is ground truth obtained in advance, a process of calculating a gradient for the weights such that the loss is reduced by passing the calculated loss through the super-resolution convolutional network model in a reverse direction, and a process of updating the weights. The backpropagation process may be referred to as an error backpropagation process. Operation S400 will be described with reference to FIGS. 10 and 11.

Thereafter, operations S100, S200 and S300 may be performed using the trained super-resolution convolutional network model (e.g., the super-resolution convolutional network model for which the training process has been completed). Operations S100, S200 and S300 may be substantially the same as those described with reference to FIG. 1.

FIG. 9 is a block diagram illustrating an image processing device according to example embodiments. The descriptions repeated with FIG. 2 will be omitted for brevity.

Referring to FIG. 9, an image processing device 102 includes a high-resolution image obtaining module 200, and may further include a training module 300.

The image processing device 102 may be substantially the same as the image processing device 100 of FIG. 2, except that the image processing device 102 further includes the training module 300.

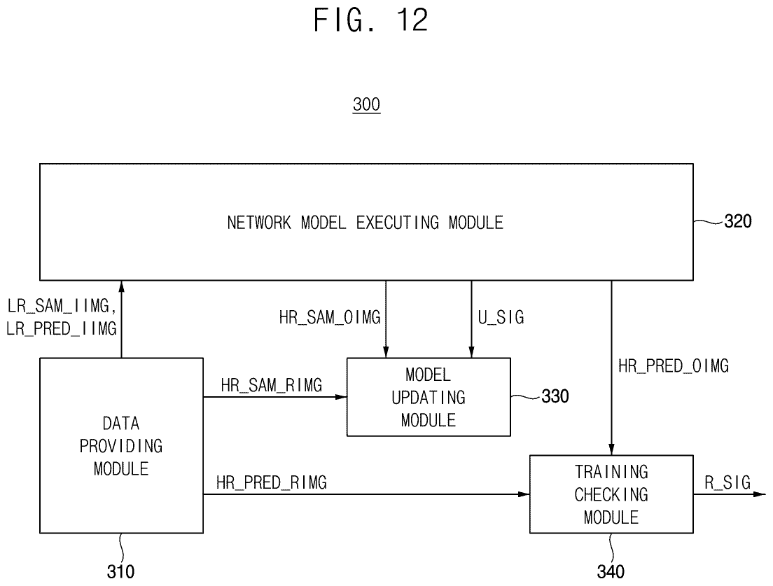

The training module 300 may perform a training process on the super-resolution convolutional network model executed by the high-resolution image obtaining module 200. In other words, the training module 300 may perform operation S400 in FIG. 8. A detailed configuration of the training module 300 will be described with reference to FIG. 12.

In an example embodiment, the high-resolution image obtaining module 200 and the training module 300 is implemented as a single integrated module. In an example embodiment, the high-resolution image obtaining module 200 and the training module 300 are implemented as separate and different modules. In an example embodiment, the high-resolution image obtaining module 200 and the training module 300 are implemented to share some components. For example, both the high-resolution image obtaining module 200 and the training module 300 may be implemented to execute the super-resolution convolutional network model, and thus components for executing the super-resolution convolutional network model may be shared by the high-resolution image obtaining module 200 and the training module 300.

In an example embodiment, the image processing device 102 is implemented as illustrated in FIG. 3. For example, both the high-resolution image obtaining module 200 and the training module 300 may be implemented in software, and the program PR in FIG. 3 may correspond to the high-resolution image obtaining module 200 and the training module 300.

FIG. 10 is a flowchart illustrating performing a training process in FIG. 8 according to an example embodiment.

Referring to FIGS. 8 and 10, when performing the training process on the super-resolution convolutional network model (operation S400), a plurality of low-resolution sample input images and a plurality of high-resolution sample reference images corresponding to the plurality of low-resolution sample input images are obtained and/or generated (operation S410). For example, the high-resolution sample reference images may represent ground truth (or correct answer information) associated with the low-resolution sample input images. For example, a high-resolution sample reference image could be generated by using a high-resolution camera to capture and image and a corresponding low-resolution sample input images could be generated by performing an operation on the high-resolution sample reference image to reduce tits resolution.

The super-resolution convolutional network model may be trained based on the plurality of low-resolution sample input images and the plurality of high-resolution sample reference images (operation S420). For example, while operation S420 is performed, a plurality of high-resolution sample output images may be generated by applying or inputting the plurality of low-resolution sample input images to the super-resolution convolutional network model, and the plurality of high-resolution sample reference images and the plurality of high-resolution sample output images may be compared with each other. For example, as the super-resolution convolutional network model is trained, a plurality of weights included in the super-resolution convolutional network model may be updated. For example, features of a low-resolution sample input image may be input to the super-resolution convolutional network model to generate an output image for comparison with a corresponding high-resolution sample reference image to update the weights.

A high-resolution prediction output image is obtained and/or generated based on the trained super-resolution convolutional network model and a low-resolution prediction input image (operation S430). Operation 5430 may be performed similarly to operations S100, S200 and S300 in FIG. 1. For example, while operation S430 is performed, a prediction residual image may be generated by sequentially performing the plurality of computing operations on the low-resolution prediction input image using the trained super-resolution convolutional network model, a prediction interpolation image may be generated by performing the interpolation operation on the low-resolution prediction input image, and the high-resolution prediction output image having a resolution higher than that of the low-resolution prediction input image may be generated by adding the prediction residual image and the prediction interpolation image.

An error value of the trained super-resolution convolutional network model may be checked based on the high-resolution prediction output image and a high-resolution prediction reference image corresponding to the low-resolution prediction input image (e.g., by comparing the high-resolution prediction output image with the high-resolution prediction reference image) (operation S440). For example, the high-resolution prediction reference image may represent ground truth associated with the low-resolution prediction input image. For example, the error value may represent a difference between the high-resolution prediction reference image and the high-resolution prediction output image.

The low-resolution prediction input image, the high-resolution prediction reference image and the high-resolution prediction output image may not be used to train the super-resolution convolutional network model, but may be used to check a result of training the super-resolution convolutional network model.

FIG. 11 is a flowchart illustrating an example of checking an error value of a trained super-resolution convolutional network model in FIG. 10 according to an example embodiment.

Referring to FIGS. 10 and 11, when checking the error value of the trained super-resolution convolutional network model (operation S440), the error value of the trained super-resolution convolutional network model is compared with a predetermined reference value (or threshold value) (operation S450).

When the error value of the trained super-resolution convolutional network model is greater than the reference value (operation S450: YES), e.g., when a consistency of the super-resolution convolutional network model does not reach a target consistency or is lower than the target consistency, the super-resolution convolutional network model is re-trained (operation S460). Operation S460 may be performed similarly to operations S410, S420 and S430. For example, additional low-resolution sample input images and additional high-resolution sample reference images corresponding thereto may be obtained, the super-resolution convolutional network model may be re-trained based on the additional low-resolution sample input images and the additional high-resolution sample reference images, an additional high-resolution prediction output image may be obtained based on the re-trained super-resolution convolutional network model and an additional low-resolution prediction input image, and the error value may be updated based on the additional high-resolution prediction output image and an additional high-resolution prediction reference image corresponding to the additional low-resolution prediction input image.

When the error value of the trained super-resolution convolutional network model is smaller than or equal to the reference value (operation S450: NO), e.g., when the consistency of the super-resolution convolutional network model reaches the target consistency or is higher than the target consistency, a result of the training process (e.g., finally updated weights) may be stored, and the training process may be terminated.

Although example embodiments are described where the super-resolution convolutional network model is re-trained until a predetermined condition (e.g., the reference value or the target consistency) is satisfied, the inventive concept is not limited thereto. For example, the super-resolution convolutional network model may be re-trained by a predetermined number of iterations at an initial operation time. For example, the super-resolution convolutional network model may re-trained a certain number of times for later use even though the its final error value remains above the reference value.

FIG. 12 is a block diagram illustrating an example of a training module included in an image processing device of FIG. 9.

Referring to FIG. 12, the training module 300 may include a data providing module 310, a network model executing module 320, a model updating module 330 and a training checking module 340.

The data providing module 310 may provide low-resolution sample input images LR_SAM_IIMG to the network model executing model 320 and high-resolution sample reference images HR_SAM_RIMG corresponding thereto to the model updating module 330, and may provide a low-resolution prediction input image LR_PRED_IIMG to the network model executing model 320 and a high-resolution prediction reference image HR_PRED_RIMG corresponding thereto to the training checking module 340. In other words, the data providing module 310 may perform operation S410 in FIG. 10, and may provide data for performing operations S430 and S440.

The network model executing module 320 may generate high-resolution sample output images HR_SAM_OIMG based on the low-resolution sample input images LR_SAM_IIMG, and may generate a high-resolution prediction output image HR_PRED_OIMG based on the low-resolution prediction input image LR_PRED_IIMG. In other words, the network model executing module 320 may perform at least a part of operation S420 and operation S430 in FIG. 10. For example, the network model executing module 320 may be implemented to execute the super-resolution convolutional network model of FIG. 6A. For example, components for executing the super-resolution convolutional network model may be shared by network model executing module 320 and the residual module 210 in FIG. 7. For example, the super-resolution convolutional network model 320 may generate high-resolution sample output images HR_SAM_OIMG based on the low-resolution sample input images LR_SAM_IIMG, and may generate the high-resolution prediction output image HR_PRED_OIMG based on the low-resolution prediction input image LR_PRED_IIMG.

The network model executing module 320 may generate an update signal U_SIG to inform the model updating module 330 to train and/or update the super-resolution convolutional network model based on the high-resolution sample reference images HR_SAM_RIMG and the high-resolution sample output images HR_SAM_OIMG. In other words, the model updating module 330 may perform at least a part of operation S420 in FIG. 10. For example, the model updating module 330 may perform at least a part of operation S420 in response to the update signal U_SIG.

The training checking module 340 may generate a result signal R_SIG representing a result of training the super-resolution convolutional network model based on the high-resolution prediction reference image HR_PRED_RIMG and the high-resolution prediction output image HR_PRED_OIMG. In other words, the training checking module 340 may perform operation S440 in FIG. 10. Based on the result signal R_SIG, the super-resolution convolutional network model may be re-trained or the training process may be terminated. For example, the result signal R_SIG may indicate that a training or a re-training of the super-resolution convolutional network model has been completed.

The training process of FIG. 10 may be described as a method of training a super-resolution convolutional network model according to example embodiments, and the training module 300 of FIG. 12 may be described as a training device for training a super-resolution convolutional network model according to example embodiments.

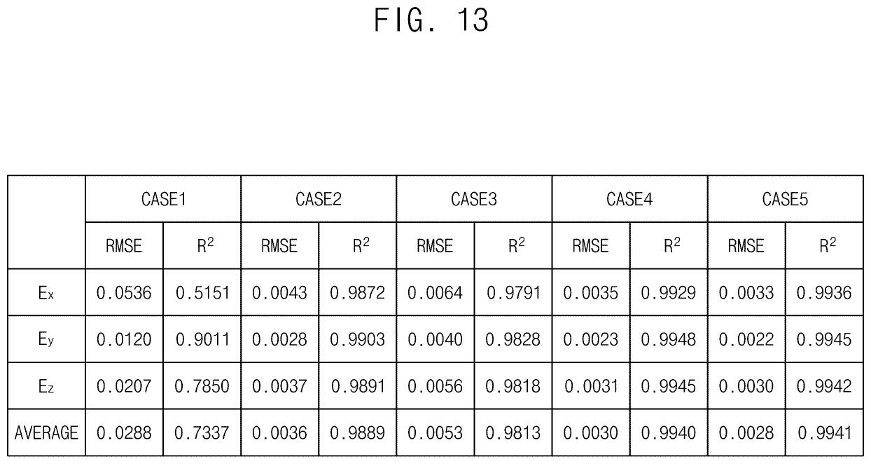

FIGS. 13, 14A, 14B, 14C, 15A, 15B, 15C, 15D, 15E and 16 are diagrams for describing performance of a method of processing an image based on super-resolution according to example embodiments.

Referring to FIG. 13, performances of various super-resolution schemes or techniques are illustrated. In FIG. 13 and subsequent figures, “CASE1” represents a case of using a comparative interpolation operation, “CASE2” represents a case of using a comparative super-resolution convolutional neural network (SRCNN), “CASE3” represents a case of using a comparative fast super-resolution convolutional neural network (FSRCNN), “CASE4” represents a case of using a comparative very deep super-resolution convolutional network (VDSR), and “CASE5” represents a case of using the FRSR according to example embodiments.

Root mean square error (RMSE) and coefficient of determination (or R² score) may be used as indicators for evaluation. The RMSE may be an index representing a difference between a predicted value and a real (or actual) value, and may be calculated based on Equation 5. For example, the smaller the RMSE, the better the performance; and the larger the RMSE, the worse the performance. The coefficient of determination may be an index representing a degree to which an estimated model is suitable for given data, and may be calculated based on Equation 6. For example, the larger the coefficient of determination, the better the performance.

$$RMSE = \sqrt{\frac{{\sum }_{i = 1}^{n} {( {Y}_{i} - \overline{Y} )}^{2}}{n}} \qquad [ Equation 5 ]$$

$${R}^{2} = \frac{{\sum }_{i = 1}^{n} ( {X}_{i} - \overline{X} ) ( {Y}_{i} - \overline{Y} )}{\sqrt{{\sum }_{i = 1}^{n} {( {X}_{i} - \overline{X} )}^{2}} \sqrt{{\sum }_{i = 1}^{n} {( {Y}_{i} - \overline{Y} )}^{2}}} \qquad [ Equation 6 ]$$

As illustrated in FIG. 13, in the case of CASE5 using the FRSR according to example embodiments, it can be seen that it has the better performance in the RMSE and the coefficient of determination evaluation, as compared to CASE1, CASE2, CASE3 and CASE4.

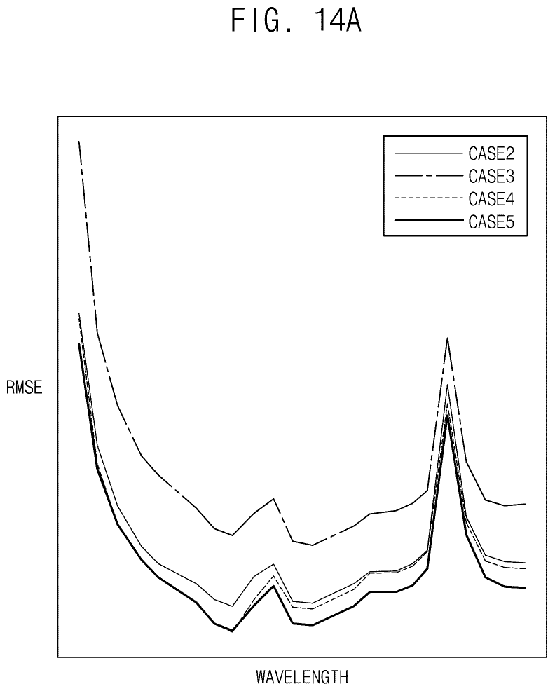

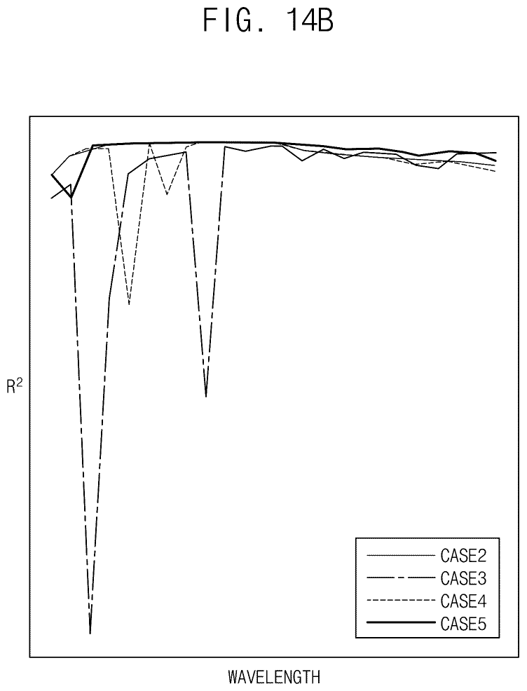

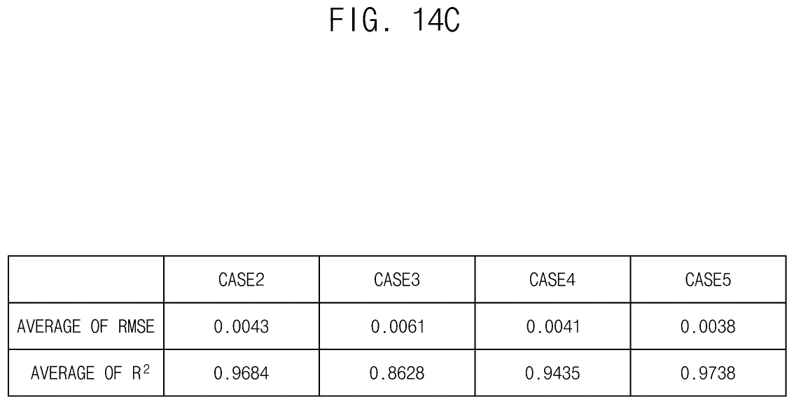

Referring to FIGS. 14A, 14B and 14C, results of comparing the RMSE and the coefficient of determination based on samples for 24 wavelengths are illustrated. In the case of CASE5 using the FRSR according to example embodiments, it can be seen that it has the better performance in the RMSE and the coefficient of determination evaluation, as compared to CASE2, CASE3 and CASE4.

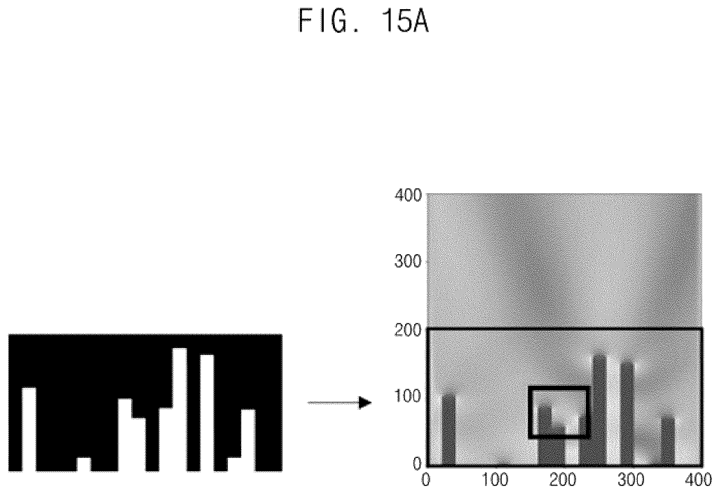

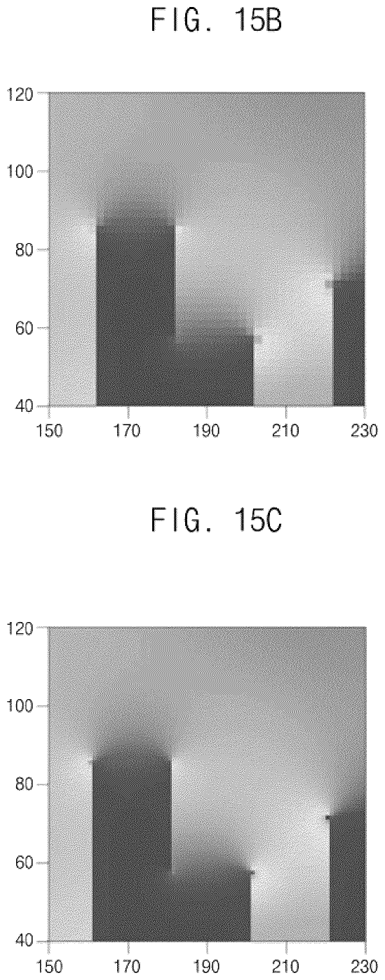

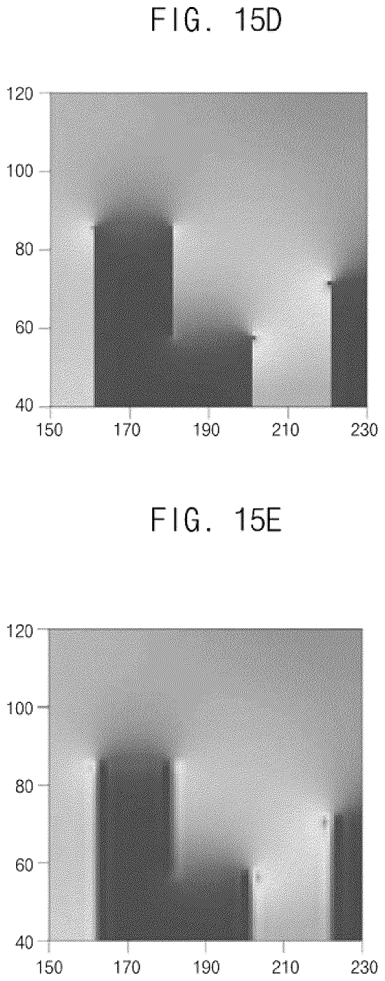

Referring to FIGS. 15A, 15B, 15C, 15D and 15E, results of generating a high-resolution image using a super-resolution process applied to a nano optical device simulation space are illustrated. An “Eₓ” component of the electromagnetic field magnitude image associated with a specific slit design at a wavelength of about 800 nm is illustrated as a heat map. FIG. 15A illustrates a slit design as an example. FIGS. 15B and 15C illustrate a low-resolution image and a corresponding high-resolution reference image (e.g., a correct answer image), respectively. FIG. 15D illustrates a high-resolution image generated using the FRSR according to example embodiments (e.g., corresponding to CASES). FIG. 15E illustrates a high-resolution image generated using the comparative interpolation operation (e.g., corresponding to CASE1). In the case of CASES using the FRSR according to example embodiments, it can be seen that the better high-resolution image is generated, as compared to CASE1.

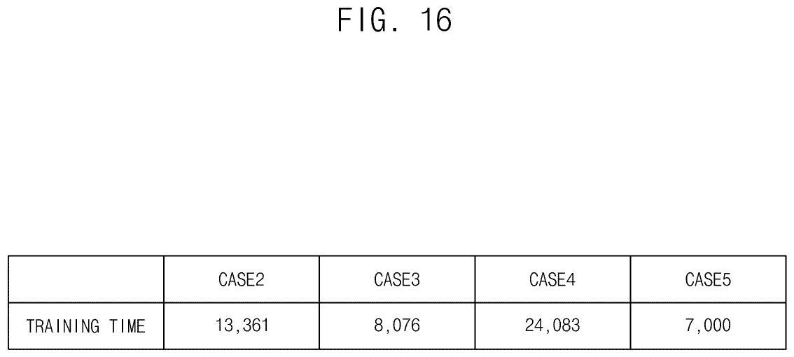

Referring to FIG. 16, time required to train about 6,720 data are illustrated. In the case of CASES using the FRSR according to example embodiments, it can be seen that the required processing time is reduced and thus a better performance is achieved, as compared to CASE2, CASE3 and CASE4.

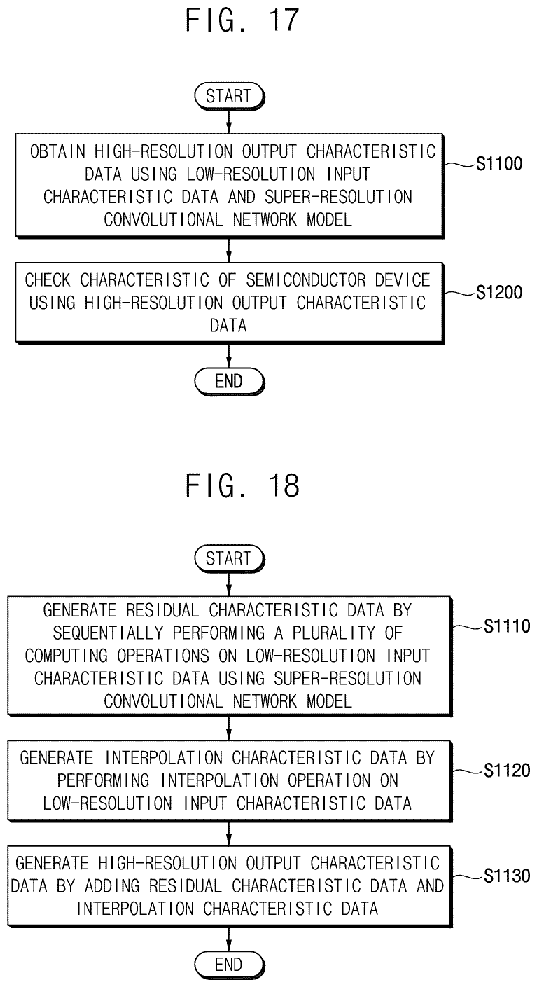

FIG. 17 is a flowchart illustrating a method of predicting a characteristic of a semiconductor device according to an example embodiment.

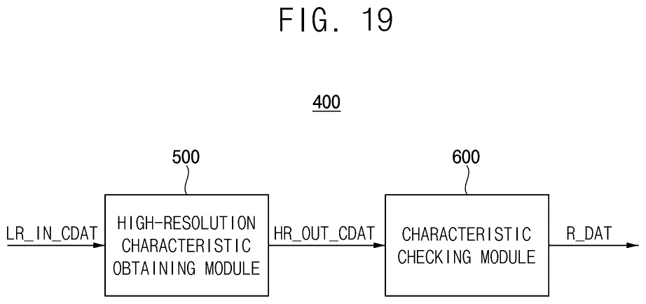

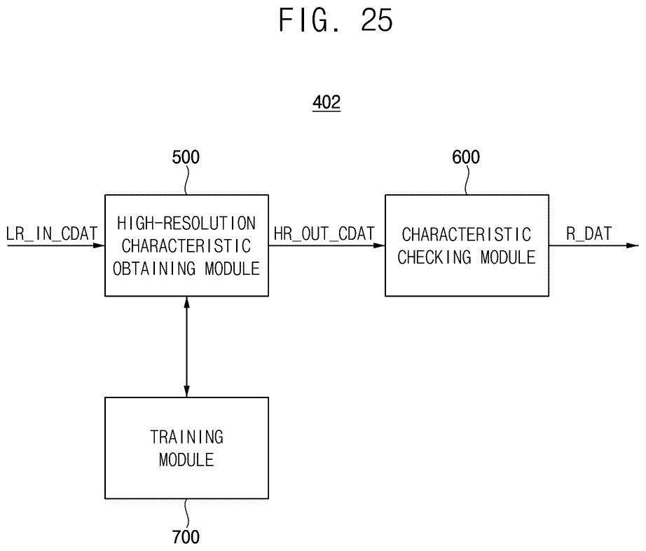

Referring to FIG. 17, a method of predicting a characteristic of a semiconductor device according to example embodiments is performed when designing and/or manufacturing the semiconductor device, and is performed by a characteristic predicting device. A detailed configuration of the characteristic predicting device will be described with reference to FIGS. 19 and 25.

In the method of predicting the characteristic of the semiconductor device according to an example embodiment, high-resolution output characteristic data is obtained using low-resolution input characteristic data and a super-resolution convolutional network model based (operation S1100). The super-resolution convolutional network model may perform residual learning and post-up sampling. The super-resolution convolutional network model may operate on the low-resolution input characteristic data to generate the high-resolution output characteristic data. The high-resolution output characteristic data and the low-resolution input characteristic data are associated with the semiconductor device. The super-resolution convolutional network model may be implemented as described with reference to FIG. 6A.

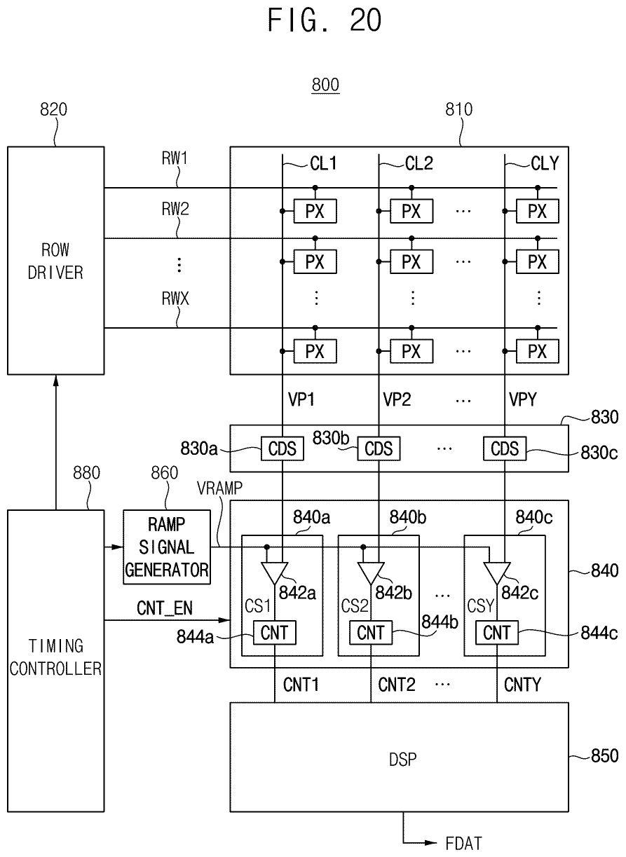

The characteristic of the semiconductor device is checked using the high-resolution output characteristic data (operation S1200). For example, the semiconductor device may be a nano optical device. For example, the semiconductor device may be an image sensor including a plurality of pixels, and may be a complementary metal-oxide semiconductor (CMOS) image sensor. A detailed configuration of the image sensor will be described with reference to FIGS. 20, 21, 22A and 22B.

For example, the characteristic of the semiconductor device may correspond to a light efficiency of the plurality of pixels included in the image sensor. For example, the characteristic (e.g., nano optical characteristic) of the semiconductor device may consist of two electric field components Eₓ and E_{y} and one magnetic field component H_{z} in terms of the magnitude of the electromagnetic field. For example, the light efficiency may be determined from the two electric field components Eₓ and E_{y} and the one magnetic field component H_{z}. For example, the characteristic of the semiconductor device may include three components similar to a red (R) component, a green (G) component and a blue (B) component of an image.

In nano optics, super-resolution may be applied so that device characteristic values included in each lattice in a lattice unit simulation space may be calculated in a finer lattice unit. When a size of the lattice is relatively large, it may be defined as low-resolution characteristic data (e.g., low-resolution image). When a size of the lattice is relatively small, it may be defined as high-resolution characteristic data (e.g., high-resolution image).

In the method of predicting the characteristic of the semiconductor device according to an example embodiment, the high-resolution characteristic data may be generated by applying the low-resolution characteristic data to the super-resolution convolutional network model. When the super-resolution convolutional network model is used, a larger amount of output characteristic values may be obtained from a smaller amount of input characteristic values, and characteristic values with increased accuracy may be obtained within a relatively short time. Accordingly, the design and manufacturing efficiency of the semiconductor devices may be increased.

FIG. 18 is a flowchart illustrating an example of obtaining high-resolution output characteristic data in FIG. 17. The descriptions repeated with FIG. 1 will be omitted for brevity.

Referring to FIGS. 17 and 18, when obtaining the high-resolution output characteristic data associated with the semiconductor device (operation S1100), residual characteristic data is generated by sequentially performing a plurality of computing operations on the low-resolution input characteristic data using the super-resolution convolutional network model (operation S1110). Interpolation characteristic data is generated by performing an interpolation operation on the low-resolution input characteristic data (operation S1120). The high-resolution output characteristic data is generated by adding the residual characteristic data and the interpolation characteristic data (operation S1130). For example, the residual characteristic data may be added to the interpolation characteristic data to generate a sum, and the high-resolution output characteristic data may be generated from the sum. The high-resolution output characteristic data may have a resolution higher than that of the low-resolution input characteristic data.

Operations S1110, S1120 and S1130 in FIG. 18 may be substantially the same as operations S100, S200 and S300 in FIG. 1, respectively, except that the term “image” is changed to “characteristic data”. When the characteristic data is implemented in the form of two-dimensional data, the term “characteristic data” may be understood to be the same as the term “image”.

FIG. 19 is a block diagram illustrating a characteristic predicting device according to an example embodiment. The descriptions repeated with FIGS. 2 and 7 will be omitted for brevity.

Referring to FIG. 19, a characteristic predicting device 400 includes a high-resolution characteristic obtaining module 500 and a characteristic checking module 600.

The high-resolution characteristic obtaining module 500 obtains and/or generates high-resolution output characteristic data HR_OUT_CDAT based on low-resolution input characteristic data LR_IN_CDAT. For example, the high-resolution characteristic obtaining module 500 may be similar to the high-resolution image obtaining module 200 in FIG. 2, and may include a residual module, an interpolation module and an adder module as described with reference to FIG. 7. In other words, the high-resolution characteristic obtaining module 500 may perform operation S1100 in FIG. 17 and operations S1110, S1120 and S1130 in FIG. 18.

The characteristic checking module 600 generates result data R_DAT representing a characteristic of a semiconductor device based on the high-resolution output characteristic data HR_OUT_CDAT. In other words, the characteristic checking module 600 may perform operation S1200 in FIG. 17.

In an example embodiment, the high-resolution characteristic obtaining module 500 and the characteristic checking module 600 are implemented as a single integrated module. In other example embodiments, the high-resolution characteristic obtaining module 500 and the characteristic checking module 600 may be implemented as separate and different modules. In some example embodiments, the characteristic predicting device 400 may be implemented as illustrated in FIG. 3. For example, both the high-resolution characteristic obtaining module 500 and the characteristic checking module 600 may be implemented in software, and the program PR in FIG. 3 may correspond to the high-resolution characteristic obtaining module 500 and the characteristic checking module 600.

FIG. 20 is a block diagram illustrating an image sensor, which is an example of a target to which a method of predicting a characteristic of a semiconductor device according to an example embodiment is applied.

Referring to FIG. 20, an image sensor 800 includes a pixel array 810 and an image sensor driver integrated circuit. The image sensor driver integrated circuit may include a row driver 820 (e.g., a driver circuit), a correlated double sampling (CDS) block 830 (e.g., CDS circuit), an analog-to-digital converting (ADC) block 840 (e.g., an analog-to-digital converter), a digital signal processor (DSP) 850, a ramp signal generator 860 and a timing controller 880 (e.g., a control circuit).

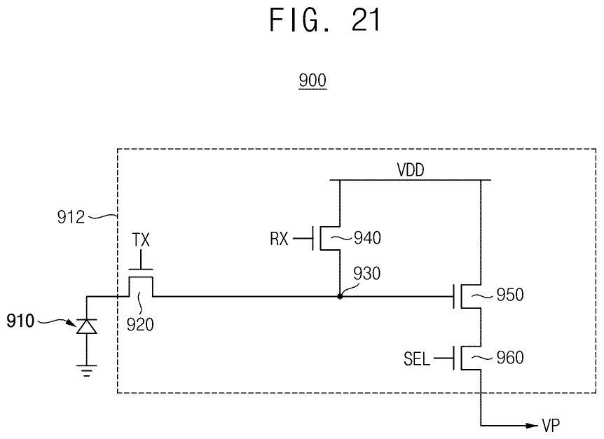

The pixel array 810 may include a plurality of pixels (or unit pixels) PX that are arranged in a matrix formation. Each of the plurality of pixels PX may be connected to a respective one of a plurality of rows RW1, RW2, . . . , RWX and a respective one of a plurality of columns CL1, CL2, . . . , CLY, where each of X and Y is a natural number greater than or equal to two. The pixel array 810 may generate a plurality of analog pixel signals VP1, VP2, . . . , VPY based on incident light. An example of each of the plurality of pixels PX will be described with reference to FIG. 21.

The row driver 820 may be connected to the plurality of rows RW1 to RWX of the pixel array 810. The row driver 820 may generate driving signals to drive the plurality of rows RW1 to RWX. For example, the row driver 820 may drive the plurality of pixels PX included in the pixel array 810 row by row.

The correlated double sampling block 830 may include a plurality of correlated double sampling circuits (CDSs) 830a, 830b, . . . , 830c. The plurality of correlated double sampling circuits 830a to 830c may be connected to the plurality of columns CL1 to CLY of the pixel array 810. The plurality of correlated double sampling circuits 830a to 830c may perform a correlated double sampling operation on the plurality of analog pixel signals VP1 to VPY output from the pixel array 810.

The analog-to-digital converting block 840 may include a plurality of analog-to-digital converters 840a, 840b, . . . , 840c. The plurality of analog-to-digital converters 840a to 840c may be connected to the plurality of columns CL1 to CLY of the pixel array 810 via the plurality of correlated double sampling circuits 830a to 830c. The plurality of analog-to-digital converters 840a to 840c may perform a column analog-to-digital converting operation that converts the plurality of analog pixel signals VP1 to VPY (e.g., a plurality of correlated double sampled analog pixel signals output from the plurality of correlated double sampling circuits 830a to 830c) into a plurality of digital signals CNT1, CNT2, CNTY in parallel (e.g., simultaneously or concurrently).

Each of the plurality of analog-to-digital converters 840a to 840c may include a respective one of a plurality of comparators 842a, 842b, 842c (e.g., a comparator circuits) and a respective one of a plurality of counters (CNTs) 844a, 844b, 844c (e.g., counter circuits). For example, the first analog-to-digital converter 840a may include the first comparator 842a and the first counter 844a. The first comparator 842a may compare the first analog pixel signal VP1 (e.g., the correlated double sampled first analog pixel signal output from the first correlated double sampling circuit 830a) with a ramp signal VRAMP to generate a first comparison signal CS1. The first counter 844a may count a level transition timing of the first comparison signal CS1 to generate the first digital signal CNT1.

Operations of the correlated double sampling block 830 and the analog-to-digital converting block 840 may be performed on the plurality of pixels PX included in the pixel array 810 row by row.

The plurality of correlated double sampling circuits 830a to 830c and the plurality of analog-to-digital converters 840a to 840c may form a plurality of column driving circuits. For example, the first correlated double sampling circuit 830a and the first analog-to-digital converter 840a may form a first column driving circuit.

The digital signal processor 850 may perform a digital signal processing operation based on the plurality of digital signals CNT1 to CNTY. The digital signal processor 850 may output frame data FDAT that is generated by the digital signal processing operation.

The ramp signal generator 860 may generate the ramp signal VRAMP. The timing controller 880 may control overall operation timings of the image sensor 800, and may generate control signals including a count enable signal CNT_EN, a clock signal (not illustrated), etc.

FIG. 21 is a circuit diagram illustrating an example of a pixel included in a pixel array included in an image sensor of FIG. 20.

Referring to FIG. 21, a pixel (or unit pixel) 900 may include a photoelectric conversion unit 910 and a signal generation unit 912.

The photoelectric conversion unit 910 may perform a photoelectric conversion operation. For example, the photoelectric conversion unit 910 may convert the incident light into photo-charges during an integration mode. If an image sensor including the pixel 900 is a CMOS image sensor, image information on an object to be captured may be obtained by collecting charge carriers (e.g., electron-hole pairs) in the photoelectric conversion unit 910 proportional to intensity of the incident light through an open shutter of the CMOS image sensor during the integration mode.

The signal generation unit 912 may generate an electric signal (e.g., an analog pixel signal VP) based on the photo-charges generated by the photoelectric conversion operation during a readout mode. If the image sensor including the pixel 900 is the CMOS image sensor, the shutter may be closed, and the analog pixel signal VP may be generated based on the image information in a form of the charge carriers during the readout mode after the integration mode. For example, as illustrated in FIG. 21, the pixel 900 may have a four-transistor structure including four transistors.

For example, the signal generation unit 912 may include a transfer transistor 920, a reset transistor 940, a driving transistor 950, a selection transistor 960 and a floating diffusion node 930. The transfer transistor 920 may be disposed between the photoelectric conversion unit 910 and the floating diffusion node 930, and may include a gate electrode receiving a transfer signal TX. For example, the transfer transistor 920 may selectively electrically connect the photoelectric conversion unit 910 with the floating diffusion node 930 in response to the transfer signal TX.

The reset transistor 940 may be disposed between a power supply voltage VDD and the floating diffusion node 930, and may include a gate electrode receiving a reset signal RX. For example, the reset transistor 940 may selectively electrically connect the power supply voltage VDD with the floating diffusion node 930 in response to the reset signal RX. The driving transistor 950 may be disposed between the power supply voltage VDD and the selection transistor 960, and may include a gate electrode connected to the floating diffusion node 930. For example, the driving transistor 950 may selectively electrically connect the power supply voltage VDD with the selection transistor 960 in response to a voltage of the floating diffusion node 930. The selection transistor 960 may be disposed between the driving transistor 950 and an output terminal outputting the analog pixel signal VP, and may include a gate electrode receiving a selection signal SEL. For example, the selection transistor 960 may selectively electrically connect the driving transistor 960 with the output terminal to output the analog pixel signal VP in response to the selection signal SEL.

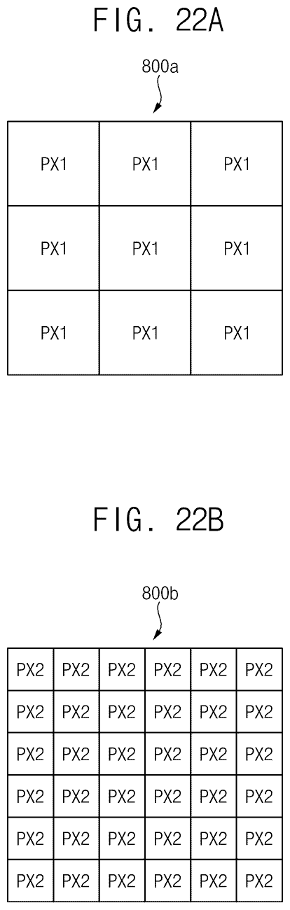

FIGS. 22A and 22B are diagrams illustrating examples of pixel structures of an image sensor of FIG. 20.

Referring to FIGS. 22A and 22B, a first image sensor 800a may include a first number of first pixels PX1, and a second image sensor 800b may include a second number of second pixels PX2. The first image sensor 800a and/or the second image sensor 800b may be used to implement the first image sensor 800. For example, the size of the second pixels PX2 included in the second image sensor 800b may be smaller than the size of the first pixels PX1 included in the first image sensor 800a. For example, the second number of second pixels included in the second image sensor 800b may be greater than the first number of first pixels PX1 included in the first image sensor 800a.

In an example embodiment, the low-resolution input characteristic data LR_IN_CDAT corresponds to a characteristic of the first image sensor 800a, and the high-resolution output characteristic data HR_OUT_CDAT corresponds to a characteristic of the second image sensor 800b. For example, the characteristics depending on changes in pixel units (or size) may be predicted in advance. For example, a characteristic value of each pixel may be collected by simulation while changing the pixel units, and/or the characteristic value of each pixel may be collected using an image sensor that is already manufactured. The super-resolution convolutional network model may be trained using the collected characteristic values, and then characteristic values of smaller pixel units may be predicted using the super-resolution convolutional network model. Therefore, it is possible to check the limit of the pixel size and to check the pixel characteristics before manufacturing.

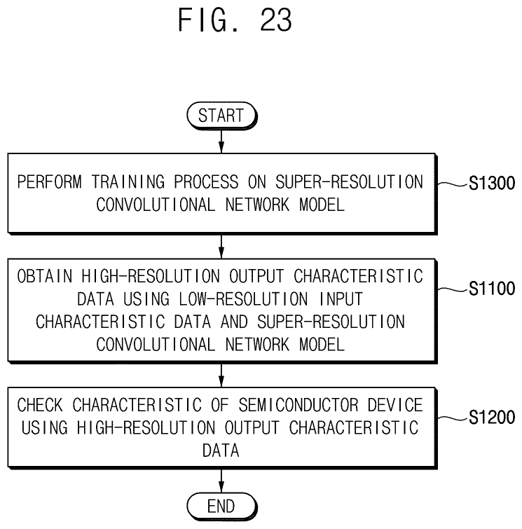

FIG. 23 is a flowchart illustrating a method of predicting a characteristic of a semiconductor device according to an example embodiment. The descriptions repeated with FIGS. 8 and 17 will be omitted for brevity.

Referring to FIG. 23, in method of predicting a characteristic of a semiconductor device according to an example embodiment, operation S1300 may be substantially the same as operation S400 in FIG. 8, and operations S1100 and S1200 may be substantially the same as those described with reference to FIG. 17.

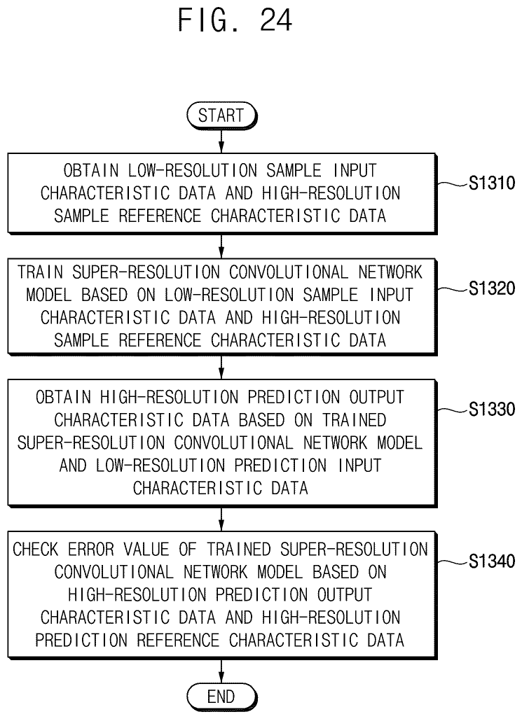

FIG. 24 is a flowchart illustrating an example of performing a training process in FIG. 23. The descriptions repeated with FIG. 10 will be omitted for brevity.

Referring to FIGS. 23 and 24, when performing the training process on the super-resolution convolutional network model (operation S1300), a plurality of low-resolution sample input characteristic data and a plurality of high-resolution sample reference characteristic data corresponding to the plurality of low-resolution sample input characteristic data are obtained (operation S1310). The super-resolution convolutional network model is trained based on the plurality of low-resolution sample input characteristic data and the plurality of high-resolution sample reference characteristic data (operation S1320). High-resolution prediction output characteristic data are obtained based on the trained super-resolution convolutional network model and the low-resolution prediction input characteristic data (operation S1330). An error value of the trained super-resolution convolutional network model is checked based on the high-resolution prediction output characteristic data and thr high-resolution prediction reference characteristic data corresponding to the low-resolution prediction input characteristic data (operation S1340). Operations S1310, S1320, S1330 and S1340 in FIG. 24 may be substantially the same as operations S410, S420, S430 and S440 in FIG. 10, respectively, except that the term “image” is changed to “characteristic data”.

FIG. 25 is a block diagram illustrating a characteristic predicting device according to an example embodiment. The descriptions repeated with FIGS. 9 and 19 will be omitted for brevity.

Referring to FIG. 25, a characteristic predicting device 402 includes a high-resolution characteristic obtaining module 500 and a characteristic checking module 600, and may further include a training module 700.

The characteristic predicting device 402 may be substantially the same as the characteristic predicting device 400 of FIG. 19, except that the characteristic predicting device 402 further includes the training module 700. The training module 700 may be substantially the same as the training module 300 in FIG. 9. For example, the training module 700 may include a data providing module, a network model executing module, a model updating module and a training checking module as described with reference to FIG. 12.

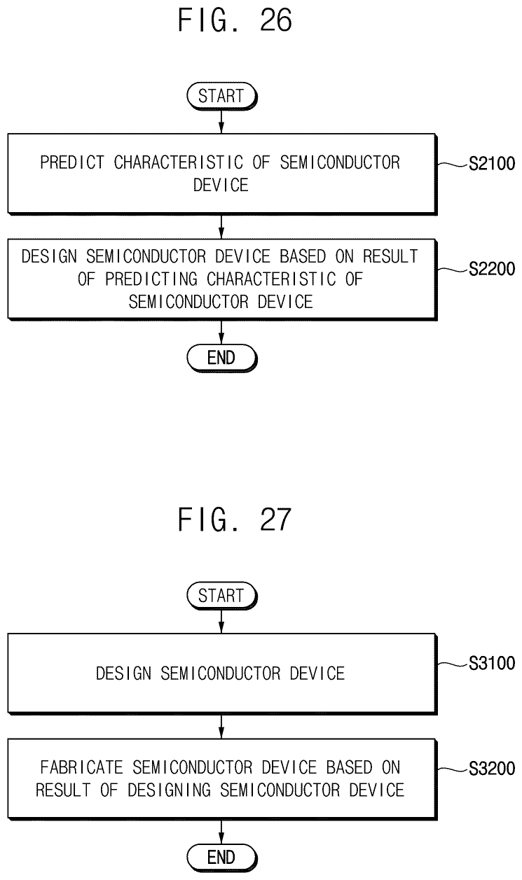

FIG. 26 is a flowchart illustrating a method of designing a semiconductor device according to an example embodiment.

Referring to FIG. 26, in a method of designing a semiconductor device according to an example embodiment, a characteristic of the semiconductor device is predicted (operation S2100), and the semiconductor device is designed based on a result of predicting the characteristic of the semiconductor device (operation S2200). Operation S2100 may be performed based on the method of predicting the characteristic of the semiconductor device according to example embodiments described with reference to FIGS. 17 through 25.

FIG. 27 is a flowchart illustrating a method of manufacturing a semiconductor device according to an example embodiment.

Referring to FIG. 27, in a method of manufacturing a semiconductor device according to an example embodiment, the semiconductor device is designed (operation S3100), and the semiconductor device is fabricated based on a result of designing the semiconductor device (operation S3200). Operation S3100 may be performed based on the method of designing the semiconductor device according to an example embodiment described with reference to FIG. 26.

Although example embodiments are described based on an image sensor, the inventive concept is not limited thereto. For example, example embodiments may be employed and/or applied to predict characteristics of various other semiconductor devices and to design and/or manufacture various other semiconductor devices using the predicted characteristics.

As will be appreciated by those skilled in the art, the inventive concepts may be embodied as a system, method, computer program product, and/or a computer program product embodied in one or more computer readable medium(s) having computer readable program code embodied thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain or store a program for use by or in connection with an instruction execution system, apparatus, or device. For example, the computer readable medium may be a non-transitory computer readable medium.

The inventive concept may be applied to various electronic devices and systems that perform the image processing, and to design various electronic devices and systems that include the semiconductor devices. For example, the inventive concept may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the example embodiments. Accordingly, all such modifications are intended to be included within the scope of the example embodiments. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of processing an image based on super-resolution, the method comprising:
sequentially performing a plurality of computing operations on a low-resolution input image using a super-resolution convolutional neural network (SRCNN) to generate a residual image;
performing an interpolation operation on the low-resolution input image to generate an interpolation image; and
adding the residual image to the interpolation image to generate a high-resolution image, the high-resolution output image having a resolution higher than a resolution of the low-resolution input image,
wherein the SRCNN includes a plurality of computation layers for performing the plurality of computing operations,
wherein the plurality of computation layers include a plurality of convolutional layers, and a deconvolutional layer for post-up-sampling, and
wherein the deconvolutional layer is a last computation layer among the plurality of computation layers.

2. The method of claim 1,
wherein the plurality of computation layers further include a plurality of leaky rectified linear unit (RELU) layers, and
wherein the plurality of convolutional layers and the plurality of leaky RELU layers are alternately arranged.

3. The method of claim 1, wherein each of the residual image and the interpolation image has a resolution higher than a resolution of the low-resolution input image.

4. The method of claim 3, wherein each of the residual image and the interpolation image has a resolution equal to a resolution of the high-resolution output image.

5. The method of claim 1, wherein the generating of the interpolation image comprises performing a bicubic interpolation operation on the low-resolution input image.

6. The method of claim 1, further comprising:
performing a training process on the SRCNN.

7. The method of claim 6, wherein performing the training process comprises:
obtaining a plurality of low-resolution sample input images and a plurality of high-resolution sample reference images corresponding to the plurality of low-resolution sample input images;
training the SRCNN based on the plurality of low-resolution sample input images and the plurality of high-resolution sample reference images;
obtaining a high-resolution prediction output image based on the trained SRCNN and a low-resolution prediction input image; and
checking an error value of the trained SRCNN based on the high-resolution prediction output image and a high-resolution prediction reference image corresponding to the low-resolution prediction input image.

8. The method of claim 7, further comprising:
re-training the SRCNN when a result of the checking indicates the error value is greater than a reference value.

9. The method of claim 7, further comprising:
terminating the training process when a result of the checking indicates the error value is smaller than or equal to a reference value.

10. The method of claim 7, wherein obtaining the high-resolution prediction output image comprises:
sequentially performing the plurality of computing operations on the low-resolution prediction input image using the trained SRCNN to generate a prediction residual image;
performing the interpolation operation on the low-resolution prediction input image to generate a prediction interpolation image; and
adding the prediction residual image to the prediction interpolation image to generate the high-resolution prediction output image, the high-resolution prediction output image having a resolution higher than a resolution of the low-resolution prediction input image.

11. The method of claim 7, wherein a plurality of weights included in the SRCNN are updated during the training.

12. A method of predicting a characteristic of a semiconductor device, the method comprising:
obtaining high-resolution output characteristic data using low-resolution input characteristic data and a super-resolution convolutional neural network (SRCNN), the high-resolution output characteristic data and the low-resolution input characteristic data being associated with the semiconductor device; and
checking the characteristic of the semiconductor device using the high-resolution output characteristic data,
wherein the obtaining of the high-resolution output characteristic data comprises:
sequentially performing a plurality of computing operations on the low-resolution input characteristic data using the SRCNN to generate residual characteristic data;
performing an interpolation operation on the low-resolution input characteristic data to generate interpolation characteristic data; and
adding the residual characteristic data to the interpolation characteristic data to generate the high-resolution output characteristic data, the high-resolution output characteristic data having a resolution higher than a resolution of the low-resolution input characteristic data,
wherein the SRCNN includes a plurality of computation layers for performing the plurality of computing operations,
wherein the plurality of computation layers include a plurality of convolutional layers, and a deconvolutional layer for post-up-sampling, and
wherein the deconvolutional layer is a last computation layer among the plurality of computation layers.

13. The method of claim 12, wherein the semiconductor device is an image sensor including a plurality of pixels.

14. The method of claim 13,
wherein the low-resolution input characteristic data corresponds to a characteristic of a first image sensor including a first number of first pixels, and
wherein the high-resolution output characteristic data corresponds to a characteristic of a second image sensor including a second number of second pixels.

15. The method of claim 14, wherein a size of the second pixels included in the second image sensor is smaller than a size of the first pixels included in the first image sensor.

16. The method of claim 14, wherein the second number of the second pixels included in the second image sensor is greater than the first number of the first pixels included in the first image sensor.

17. The method of claim 13, wherein the characteristic of the semiconductor device corresponds to a light efficiency of the plurality of pixels included in the image sensor.

18. The method of claim 12, further comprising:
performing a training process on the SRCNN.

19. The method of claim 18, wherein performing the training process comprises:
obtaining a plurality of low-resolution sample input characteristic data and a plurality of high-resolution sample reference characteristic data corresponding to the plurality of low-resolution sample input characteristic data;
training the SRCNN based on the plurality of low-resolution sample input characteristic data and the plurality of high-resolution sample reference characteristic data;
obtaining high-resolution prediction output characteristic data based on the trained SRCNN and low-resolution prediction input characteristic data; and
checking an error value of the trained SRCNN based on the high-resolution prediction output characteristic data and high-resolution prediction reference characteristic data corresponding to the low-resolution prediction input characteristic data.

20. A method of predicting light efficiency of an image sensor, the method comprising:
sequentially performing a plurality of computing operations on a low-resolution input image using a super-resolution convolutional neural network (SRCNN) to generate a residual image;
performing a bicubic interpolation operation on the low-resolution input image to generate an interpolation image;
adding the residual image to the interpolation image to generate a high-resolution output image, the high-resolution output image having a resolution higher than a resolution of the low-resolution input image; and
predicting the light efficiency of a plurality of pixels of the image sensor using the high-resolution output image,
wherein the SRCNN includes a plurality of convolutional layers, a plurality of leaky rectified linear unit (RELU) layers, and a deconvolutional layer for post-up-sampling,
wherein the plurality of convolutional layers and the plurality of leaky RELU layers are alternately arranged,
wherein the deconvolutional layer is a last layer of the SRCNN,
wherein each of the residual image and the interpolation image has a resolution higher than a resolution of the low-resolution input image and equal to a resolution of the high-resolution output image.
